(19) United States
(12) Patent Application Publication
(10) Pub. No.: US 2008/0173871 A1
(43) Pub. Date: Jul. 24, 2008

(54) Display Device and Manufacturing Method of Display Device

(76) Inventors: Takeshi Noda, Mobara (JP); Takahiro Kamo, Shibuya (JP); Hideaki Shimmoto, Toyokawa (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/939,073

(22) Filed: Nov. 13, 2007

(30) Foreign Application Priority Data
Nov. 13, 2006 (JP) 2006-306853

(51) Int. Cl. H01L 33/00; H01L 21/00

(52) U.S. Cl. 257/59; 438/30; 257/E33.001; 257/E21.001

(57) ABSTRACT

In a display device which includes MIS transistors having semiconductor layers thereof formed of an amorphous semiconductor and MIS transistors having semiconductor layers thereof including a polycrystalline semiconductor, the present invention can enhance crystallinity of the semiconductor layers formed of the polycrystalline semiconductor when the respective MIS transistors adopt the bottom gate structure. In the display device, first MIS transistors formed in a first region of a substrate and second MIS transistors formed in a second region different from the first region respectively have a gate electrode thereof between the substrate and the semiconductor layer, the first MIS transistor has the semiconductor layer thereof formed of only the amorphous semiconductor, the second MIS transistor has the semiconductor layer thereof including the polycrystalline semiconductor, and a gate electrode of the second MIS transistor has a thickness smaller than a thickness of a gate electrode of the first MIS transistor.

The present application claims priority from Japanese application JP2006-306853 filed on Nov. 13, 2006, the content of which is hereby incorporated by reference into this application.

### BACKGROUND OF THE INVENTION

The present invention relates to a display device and a manufacturing method of a display device, and more particularly to a technique which is effectively applicable to a display device which forms MIS transistors on a display region and a peripheral region outside the display region.

Conventionally, as a liquid crystal display device, there has been known a so-called active-matrix-type liquid crystal display device. Such an active-matrix-type liquid crystal display device includes a liquid crystal display panel which is formed by sealing a liquid crystal material between a pair of substrates, wherein TFT elements (MIS transistors including MOS transistors) which are used as active elements (also referred to as switching elements) are arranged in a matrix array on a display region of one substrate (hereinafter referred to as a TFT substrate) out of the above-mentioned pair of substrates.

The TFT substrate of the liquid crystal display panel includes a plurality of scanning signal lines and a plurality of video signal lines, wherein gate electrodes of the TFT elements are connected to the scanning signal lines, and either one of drain electrodes or source electrodes of the TFT elements are connected to the video signal lines.

Further, in the conventional liquid crystal display device, the plurality of video signal lines of the TFT substrate is connected to a semiconductor package such as a TCP or a COF on which driver IC chips referred to as data drivers are mounted, for example, and the plurality of scanning signal lines of the TFT substrate is connected to a semiconductor package such as a TCP or a COF on which driver IC chips which are referred to as scanning drivers or gate drivers are mounted, for example. Further, depending on a kind of the liquid crystal display device, the respective driver IC chips may be directly mounted on the TFT substrate.

Still further, with respect to a recent liquid crystal display device, there has been also proposed a method which directly forms drive circuits having functions substantially equal to functions of the respective driver IC chips outside the display region of the TFT substrate (hereinafter referred to as a peripheral region) in place of using the above-mentioned respective driver IC chips.

In directly forming the drive circuits on the peripheral region of the TFT substrate, for example, by allowing a large number of MOS transistors which constitutes the drive circuit to have the same constitution as the TFT elements in the display region, it is also possible to simultaneously form the MOS transistors of the drive circuits with the TFT elements in the display region.

However, it is necessary to operate the MOS transistors of the drive circuits at a high speed compared to the TFT elements in the display region. Accordingly, it is desirable to form a semiconductor layer of the MOS transistor of the drive circuit using polycrystalline silicon having high carrier mobility.

In forming the semiconductor layer of the MOS transistor of the drive circuit using polycrystalline silicon, for example, an amorphous silicon film is formed on a whole surface of the substrate and, thereafter, energy beams are radiated to the amorphous silicon film using an excimer laser or a continuous oscillation laser or the like to melt and crystallize the amorphous silicon film thus forming the amorphous silicon film into polycrystalline film and, thereafter, patterning is applied to the amorphous silicon film.

Here, by simultaneously forming amorphous silicon in the display region into polycrystalline silicon, for example, the semiconductor layer of the TFT element in the display region can also be formed using polycrystalline silicon. However, with respect to the TFT substrate having a large area which is used in a large-sized display device such as a liquid crystal television receiver set, a large quantity of energy is necessary for radiating laser beams to a whole surface of the TFT substrate and, at the same time, time necessary for forming the display region into polycrystalline silicon is prolonged thus worsening the productivity of the TFT substrate.

Accordingly, recently, there has been proposed a method in which, out of an amorphous silicon film which is formed on a whole surface of a substrate, energy beams such as laser beams are radiated to form the amorphous silicon film only in a region where MOS transistors of drive circuits which are operated (driven) at a high speed are formed into polycrystalline silicon, for example (see patent document 1 (JP-A-2003-124136), for example). Due to such a method, for example, semiconductor layers of the TFT elements in a display region are formed using amorphous silicon, and the MOS transistors of the drive circuits are formed using polycrystalline silicon.

Patent Document 1: JP-A-2003-124136

### SUMMARY OF THE INVENTION

Here, when the semiconductor layers of the TFT elements in the display region are formed using amorphous silicon as described above, it is desirable to provide the TFT element with the structure which includes a gate electrode between an insulation substrate such as a glass substrate and the semiconductor layer (hereinafter, referred to as the bottom gate structure). Here, to enhance the productivity of the TFT substrate, it is also desirable to provide the MOS transistor of the drive circuit in a peripheral region with the bottom gate structure.

However, to provide the MOS transistor of the drive circuit in the peripheral region with the bottom gate structure, in a step for forming the semiconductor layer, the formation of amorphous silicon into polycrystalline silicon gives rise to the following drawbacks, for example.

First of all, a material used for forming the gate electrode possesses high heat conductivity and hence, when continuous oscillation laser beams are radiated to the gate electrode, energy necessary for melting and crystallizing amorphous silicon on the gate electrode is increased compared to a portion where the gate electrode is not formed. Accordingly, it is necessary to increase energy of the beams to be radiated thus giving rise to a drawback that the productivity is lowered.

Further, in the semiconductor layer of the TFT element (MOS transistor) having the bottom gate structure, a portion of the semiconductor layer which overlaps the gate electrode in a plan view is used as a channel region, and a portion of the semiconductor layer outside the overlapping portions is used as a drain region and a source region and hence, to focus on one semiconductor layer, it is desirable to arrange the crystallinities of the respective portions (regions). However, there exists a drawback that it is difficult to arrange crystallinity of the channel region over the gate electrode and the crystallinity of the drain region and the source region outside the channel region due to the influence of heat conductivity of the gate electrode. Here, for example, when energy of laser beams is set such that the semiconductor film over the gate electrode can obtain desired crystal grains, the energy becomes excessively large with respect to portions other than the gate electrode thus giving rise to a possibility that the semiconductor film induces an ablation. Further, there also arises a drawback that the semiconductor film over the gate electrode exhibits different crystallinity between above an end portion of the gate electrode and above a center portion of the gate electrode. In this manner, due to the influence of heat conductivity of the gate electrode, an energy range which allows the acquisition of substantially equal crystal grains becomes narrow between over the gate electrode and above portions outside the gate electrode thus making the manufacture of the TFT element having the bottom gate structure difficult.

Further, in the TFT element having the bottom gate structure, a film thickness of the gate electrode directly appears as a stepped portion of the semiconductor layer. Accordingly, for example, when a melting time of the semiconductor layer is long as in the case of the formation of polycrystalline silicon using continuous oscillation laser beams, molten silicon moves from above the stepped portion to below the stepped portion thus also giving rise to a drawback that the film is liable to be easily peeled off at the stepped portion.

Further, as a technique which reduces the influence of heat conductivity of the gate electrode, there has been known that a method which decreases a film thickness of the gate electrode is effective to reduce such an influence, for example. However, this method increases wiring resistances of the gate electrodes of the TFT elements and the scanning signal lines in the display region thus giving rise to a drawback that the power consumption is increased or defects attributed to the delay of signals in pixel portions are liable to easily occur.

Further, the temperature of the gate electrode is elevated to high temperature in forming amorphous silicon into polycrystalline silicon and hence, when the MOS transistor of the drive circuit adopts the bottom gate structure, it is necessary to form the gate electrode using a high-melting-point material such as Mo (molybdenum), W (tungsten), Cr (chromium), Ta (tantalum) or an MoW alloy, for example. However, these high-melting-point materials exhibit high electric resistances compared to the electric resistance of Al (aluminum) or the like and hence, when a film thickness of the gate electrode is decreased, there arises a drawback that levels of the wiring resistances become more conspicuous.

Still further, as the technique which reduces the influence of heat conductivity of the gate electrode, besides the technique which decreases a thickness of the gate electrode, there has been known a technique which increases the film thickness of a gate insulation film, for example. However, this method is liable to easily bring about lowering of ION and the increase of fluctuation of Vₜₕ among transistor properties thus giving rise to a drawback such as difficulty in operating circuits. Accordingly, the technique is not always effective.

Accordingly, the present invention has been made to overcome such drawbacks, and it is an object of the present invention to provide, for example, a technique which can, in a display device which includes MIS transistors each of which has a semiconductor layer thereof formed of an amorphous semiconductor and MIS transistors each of which has a semiconductor layer thereof including a polycrystalline semiconductor, improve the crystallinity of the semiconductor layer having the polycrystalline semiconductor when the respective MIS transistors adopt the bottom gate structure.

It is another object of the present invention to provide, for example, a technique which can, in a display device which includes MIS transistors each of which has a semiconductor layer thereof formed of an amorphous semiconductor and MIS transistors each of which has a semiconductor layer thereof including a polycrystalline semiconductor, improve productivity and a manufacturing yield rate when the respective MIS transistors adopt the bottom gate structure.

The above-mentioned and other objects and novel features of the present invention will become apparent from the description of this specification and attached drawings.

The following is an explanation of the summary of typical inventions among the inventions disclosed in this specification.

(1) The present invention provides a display device having MIS transistors each of which is formed by stacking a conductive layer, an insulation layer and a semiconductor layer on a substrate, wherein first MIS transistors formed in a first region of the substrate and second MIS transistors formed in a second region different from the first region respectively have gate electrodes thereof between the substrate and the semiconductor layers, the first MIS transistor has the semiconductor layer thereof formed of only an amorphous semiconductor, and the second MIS transistor has the semiconductor layer thereof including a polycrystalline semiconductor, and a gate electrode of the second MIS transistor has a thickness smaller than a thickness of a gate electrode of the first MIS transistor.

(2) In the display device having the constitution (1), the gate electrode of the first MIS transistor has wiring resistance lower than wiring resistance of the gate electrode of the second MIS transistor.

(3) In the display device having the constitution (1) or (2), the gate electrode of the second MIS transistor has heat conductivity lower than heat conductivity of the gate electrode of the first MIS transistor.

(4) In the display device having any one of the constitutions (1) to (3), the gate electrode of the first MIS transistor and the gate electrode of the second MIS transistor differ from each other in the stacking constitution of the conductive layer.

(5) In the display device having the constitution (4), the gate electrode of the first MIS transistor includes one or more conductive layers in addition to the stacking constitution of the conductive layer of the gate electrode of the second MIS transistor.

(6) In the display device having the constitution (1) or (2), the gate electrode of the first MIS transistor and the gate electrode of the second MIS transistor have the same stacking constitution of the conductive layer.

(7) In the display device having any one of the constitutions (1) to (6), the first region is a display region which displays videos or images, and the second region is a region which is arranged outside the display region and forms a drive circuit thereon.

(8) In the display device having the constitution (7), the display device includes scanning signal lines having the same stacking constitution as the gate electrodes of the first MIS transistors and being integrally formed with the gate electrodes of the first MIS transistors.

(9) The present invention provides a manufacturing method of a display device which includes an insulation substrate, first MIS transistors which are formed on a first region on the insulation substrate and have semiconductor layers thereof formed of only an amorphous semiconductor, and second MIS transistors which are formed on the second region on the insulation substrate and have semiconductor layers thereof including a polycrystalline semiconductor, the manufacturing method including the steps of forming gate electrodes on the insulation substrate; forming a gate insulation film which covers the gate electrodes; forming an amorphous semiconductor film on the gate insulation film; and melting and crystallizing only the amorphous semiconductor film in the second region out of the first region and the second region thus reforming the amorphous semiconductor film into polycrystalline semiconductor film, wherein the step for forming the gate electrodes comprises a first step for forming a first conductive layer in the first region and the second region, and a second step for forming a second conductive layer only in the first region out of the first region and the second region, the step being a step in which the gate electrode of the first MIS transistor having the first conductive layer and the second conductive layer, and the gate electrode of the second MIS transistor having the first conductive layer and having a film thickness smaller than a film thickness of the gate electrode of the first MIS transistor are formed.

(10) In the manufacturing method of the display device having the constitution (9), the second step is performed after the first step, and the second step is performed such that the second conductive layer is formed in the first region and the second region and, thereafter, the second conductive layer formed in the second region is removed.

(11) In the manufacturing method of the display device having the constitution (9), the second step is performed before the first step, and the second step is performed such that the second conductive layer is formed in the first region and the second region and, thereafter, the second conductive layer formed in the second region is removed.

(12) In the manufacturing method of the display device having any one of the constitutions (9) to (11), the first conductive layer and the second conductive layer are formed of the same material.

(13) In the manufacturing method of the display device having any one of the constitutions (9) to (11), the first conductive layer and the second conductive layer are formed of materials which differ from each other, and the first conductive layer is formed of a material having heat conductivity lower than heat conductivity of a material for forming the second conductive layer.

(14) In the manufacturing method of the display device having any one of the constitutions (9) to (11), the second conductive layer is formed of a material having wiring resistance lower than wiring resistance of a material for forming the first conductive layer.

(15) The manufacturing method of the display device having the constitution (9) includes; a step for forming the first conductive layer and the second conductive layer sequentially on the insulation substrate; a step for forming a first resist film which covers the second conductive layer, has a thickness larger than 0 in a region where the gate electrode of the second MIS transistor is formed, and has a thickness smaller than a thickness in a region where the gate electrode of the first MIS transistor is formed; a step for removing the first conductive layer and the second conductive layer using the first resist film as a mask; a step for forming a second resist film having a thickness of 0 in the region where the gate electrode of the second MIS transistor is formed and having a thickness larger than 0 in the region where the gate electrode of the first MIS transistor is formed by decreasing a thickness of the first resist film; and a step for removing the second conductive layer in the region where the gate electrode of the second MIS transistor is formed using the second resist film as a mask.

(16) In the manufacturing method of the display device having any one of the constitutions (9) to (15), the first region is a display region which displays videos or images thereon, and the second region is a region which is arranged outside the display region and forms a drive circuit thereon.

(17) In the manufacturing method of the display device having the constitution (16), the display device includes scanning signal lines having the same stacking constitution as the gate electrodes of the first MIS transistors and being integrally formed with the gate electrodes of the first MIS transistors.

According to the display device and the manufacturing method thereof of the present invention, for example, even when both of the first MIS transistor which has the semiconductor layer thereof formed of the amorphous semiconductor and the second MIS transistor which has the semiconductor layer thereof including a polycrystalline semiconductor adopt the bottom gate structure, it is possible to improve the crystallinity of the semiconductor layer (polycrystalline semiconductor) of the second MIS transistor. Accordingly, the operation property of the drive circuit in the second region which is formed using the second MIS transistor can be enhanced and, at the same time, the lowering of the operation property of the first MIS transistor can be prevented.

Further, according to the manufacturing method of the display device of the present invention, productivity and a manufacturing yield rate of the display device can be enhanced.

### BRIEF DESCRIPTION OF THE DRAWINGS

FIG. 1A is a schematic plan view showing one example of the schematic constitution of a liquid crystal display panel;

FIG. 1B is a schematic cross-sectional view showing one example of the cross-sectional constitution of the liquid crystal display panel taken along a line A-A′ in FIG. 1A;

FIG. 2 is a schematic plan view showing one example of the schematic constitution of a TFT substrate to which the present invention is desirably applicable;

FIG. 3 is a schematic circuit diagram showing one example of the circuit constitution of one pixel of the liquid crystal display panel;

FIG. 4A is a schematic plan view showing one example of the schematic constitution of a TFT element in a display region of the TFT substrate to which the present invention is applied;

FIG. 4B is a schematic plan view showing one example of the schematic constitution of a MOS transistor of a peripheral circuit of the TFT substrate to which the present invention is applied;

FIG. 4C is a schematic cross-sectional view showing one example of the cross-sectional constitution of the TFT substrate taken along a line B-B′ in FIG. 4A and one example of the cross-sectional constitution of the TFT substrate taken along a line C-C′ in FIG. 4B in a juxtaposed manner;

FIG. 5 is a schematic cross-sectional view showing a constitutional feature of the TFT substrate of an embodiment 1 according to the present invention;

FIG. 6A to FIG. 6E are schematic cross-sectional views for explaining a manufacturing method of gate electrodes of the TFT substrate of the embodiment 1;

FIG. 7A is a schematic plan view showing the schematic constitution of a substrate immediately after forming an amorphous silicon film;

FIG. 7B is a schematic cross-sectional view of the substrate taken along a line D-D′ in FIG. 7A;

FIG. 7C is a schematic cross-sectional view of the substrate showing a region where the gate electrode of the MOS transistor is formed in a peripheral region and a region where the gate electrode of the TFT element is formed in the display region in the cross-sectional view shown in FIG. 7B in an enlarged juxtaposed manner;

FIG. 8A is a schematic perspective view showing one example of a method for reforming amorphous silicon into polycrystalline silicon;

FIG. 8B is a schematic plan view showing the schematic constitution of a semiconductor layer in a region which is formed into polycrystalline silicon;

FIG. 9 is a schematic cross-sectional view for explaining the manner of operation and advantageous effects of the manufacturing method of a TFT substrate of the embodiment 1;

FIG. 10A to FIG. 10F are schematic cross-sectional views for explaining a modification of the manufacturing method of a TFT substrate of the embodiment 1;

FIG. 11 is a schematic cross-sectional view for explaining a variation of a TFT substrate of the embodiment 1;

FIG. 12 is a schematic cross-sectional view showing a constitutional feature of a TFT substrate of an embodiment 2 according to the present invention;

FIG. 13A to FIG. 13E are schematic cross-sectional views for explaining a manufacturing method of gate electrodes of the TFT substrate of the embodiment 2;

FIG. 14A is a schematic cross-sectional view showing one example of the cross-sectional constitution of the gate electrode in a display region and the gate electrode in a peripheral region;

FIG. 14B is a schematic cross-sectional view showing one example of the cross-sectional constitution of a connecting portion between a scanning signal line in the display region and a scanning signal line in the peripheral region;

FIG. 15 is a schematic plan view for explaining a modification of the planar constitution of the TFT element shown in FIG. 4A;

FIG. 16A is a schematic plan view showing another example of the schematic constitution of the TFT element in the display region of the TFT substrate to which the present invention is applied;

FIG. 16B is a schematic plan view showing another example of the schematic constitution of the MOS transistor of the peripheral circuit of the TFT substrate to which the present invention is applied; and

FIG. 16C is a schematic cross-sectional view showing one example of the cross-sectional constitution of the TFT substrate taken along a line E-E′ in FIG. 16A and one example of the cross-sectional constitution of the TFT substrate taken along a line F-F′ in FIG. 16B in a juxtaposed manner.

### DESCRIPTION OF THE PREFERRED EMBODIMENTS

Hereinafter, the present invention is explained in detail in conjunction with embodiments by reference to drawings.

Here, in all drawings for explaining the embodiments, parts having identical functions are given same symbols and their repeated explanation is omitted.

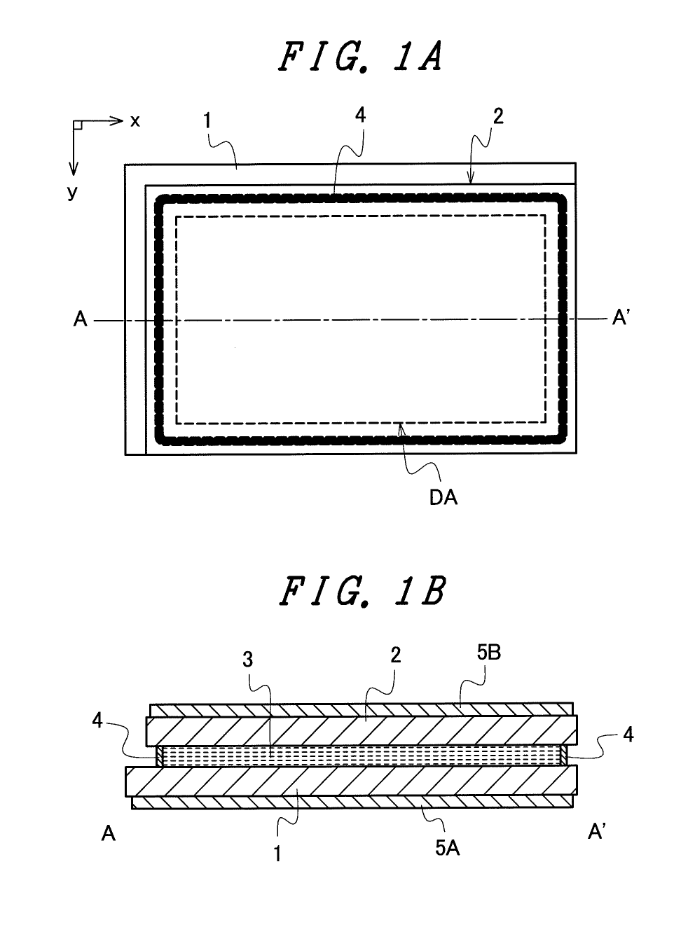

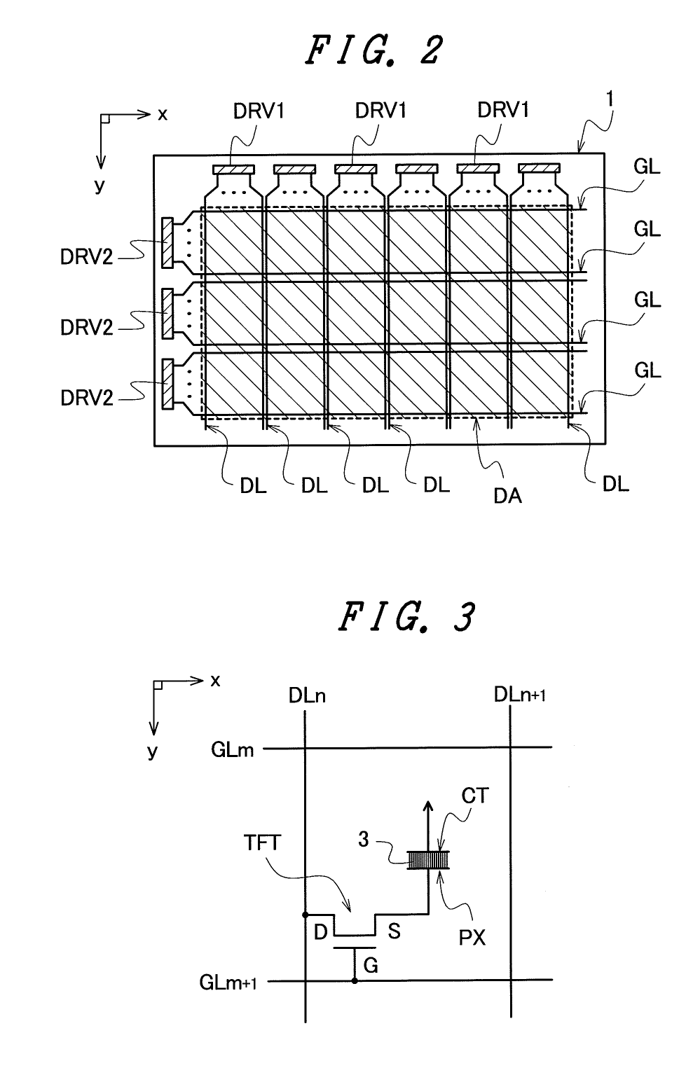

FIG. 1A, FIG. 1B, FIG. 2 and FIG. 3 are schematic views showing one example of the schematic constitution of a display panel (a display device) according to the present invention.

FIG. 1A is a schematic plan view showing one example of the schematic constitution of a liquid crystal display panel. FIG. 1B is a schematic cross-sectional view showing one example of the cross-sectional constitution of the liquid crystal display panel taken along a line A-A′ in FIG. 1A. FIG. 2 is a schematic plan view showing one example of the schematic constitution of a TFT substrate to which the present invention is desirably applicable. FIG. 3 is a schematic circuit diagram showing one example of the circuit constitution of one pixel of the liquid crystal display panel.

The present invention is applicable to, for example, an active-matrix-type liquid crystal display panel (hereinafter, simply referred to as a liquid crystal display panel) used in a liquid crystal display device such as a liquid crystal display for a liquid crystal television receiver set or a personal computer (PC).

The liquid crystal display panel is, for example, as shown in FIG. 1A and FIG. 1B, a display panel which seals a liquid crystal material 3 between two (a pair of) substrates consisting of a first substrate 1 and a second substrate 2. Here, the first substrate 1 and the second substrate 2 are adhered to each other using an annular sealing material 4 which is provided outside a display region DA on which a video, an image or the like is displayed, and the liquid crystal material 3 is sealed in the space surrounded by the first substrate 1, the second substrate 2 and the sealing material 4. Further, when the liquid crystal display panel is of a transmissive type or of a transflective type, polarizers 5A, 5B are adhered to surfaces of the first substrate 1 and the second substrate 2 which face the outside, for example. Here, a phase difference plate having one to several layers may be arranged between the first substrate 1 and the polarizer 5A and between the second substrate 2 and the polarizer 5B.

The first substrate 1 of the liquid crystal display panel is referred to as a TFT substrate in general, wherein on an insulation substrate such as a glass substrate, a plurality of scanning signal lines, a plurality of video signal lines, TFT elements (switching elements) which are arranged with respect to a plurality of respective pixels which constitutes a display region DA, pixel electrodes and the like are formed.

On the first substrate (hereinafter, referred to as a TFT substrate) 1, for example, as shown in FIG. 2, a plurality of scanning signal lines GL which extends in the x direction in an elongated manner is arranged in parallel with the y direction, and a plurality of video signal lines DL which extends in the y direction in an elongated manner is arranged in parallel with the x direction.

In the TFT substrate 1 having such a constitution, a region which is surrounded by two neighboring scanning signal lines GL and two neighboring video signal lines DL corresponds to one pixel region. A TFT element, a pixel electrode and the like are arranged in each pixel region. Here, as shown in FIG. 3, for example, to focus on the pixel in which the pixel region is constituted of a region surrounded by two neighboring scanning signal lines GLₘ, GLₘ₊₁ and two neighboring video signal lines DLₙ, DLₙ₊₁, the TFT element which is arranged for each pixel has a gate (G) thereof connected to one scanning signal line GLₘ₊₁ out of two neighboring scanning signal lines GLₘ, GLₘ₊₁. Here, the TFT element has, for example, a drain (D) thereof connected to one video signal line DLₙ out of two neighboring video signal lines DLₙ, DLₙ₊₁, and has a source (S) thereof connected to the pixel electrode PX. Further, the pixel electrode PX forms a pixel capacitance together with a common electrode CT (also referred to as a counter electrode) and the liquid crystal material 3. Here, the common electrode CT may be formed on a counter substrate 2 or may be formed on the TFT substrate 1.

Further, as shown in FIG. 2, for example, it is desirable to apply the present invention to the TFT substrate 1 on which a first drive circuit DRV1 and a second drive circuit DRV2 are integrally formed on the insulation substrate as internal circuits outside the display region DA. The first drive circuit DRV1 and the second drive circuit DRV2 are respectively formed of an integrated circuit which is constituted by combining a large number of semiconductor elements such as MOS transistors or diodes. In a manufacturing step of the TFT substrate 1, the first drive circuit DRV1 and the second drive circuit DRV2 are formed together with the scanning signal lines GL, the video signal lines DL, the TFT elements in the display region DA and the like. Hereinafter, the MOS transistors of the first drive circuit DRV1 and the second drive circuit DRV2 are referred to as the MOS transistors in the peripheral region.

The first drive circuit DRV1 is a circuit having a function equivalent to a function of a chip-shaped data driver IC used in a conventional liquid crystal display device, and includes a circuit for generating the video signal (gray scale data) inputted to the respective video signal lines DL, a circuit which controls timing at which the generated video signal is outputted to the respective video signal lines DL and the like, for example. Further, the second drive circuit DRV2 is a circuit having a function equivalent to a function of a chip-shaped scanning driver IC used in the conventional liquid crystal display device, and includes a circuit for generating the scanning signal inputted to the respective scanning signal lines GL, a circuit for controlling timing at which the generated scanning signal is outputted to the respective scanning signal lines GL and the like, for example.

Here, although it is desirable to form the first drive circuit DRV1 and the second drive circuit DRV2 inside the sealing material 4, that is, between the sealing material 4 and the display region DA, the first drive circuit DRV1 and the second drive circuit DRV2 may be formed in a region which overlaps the sealing material 4 in a plan view or outside the sealing material 4.

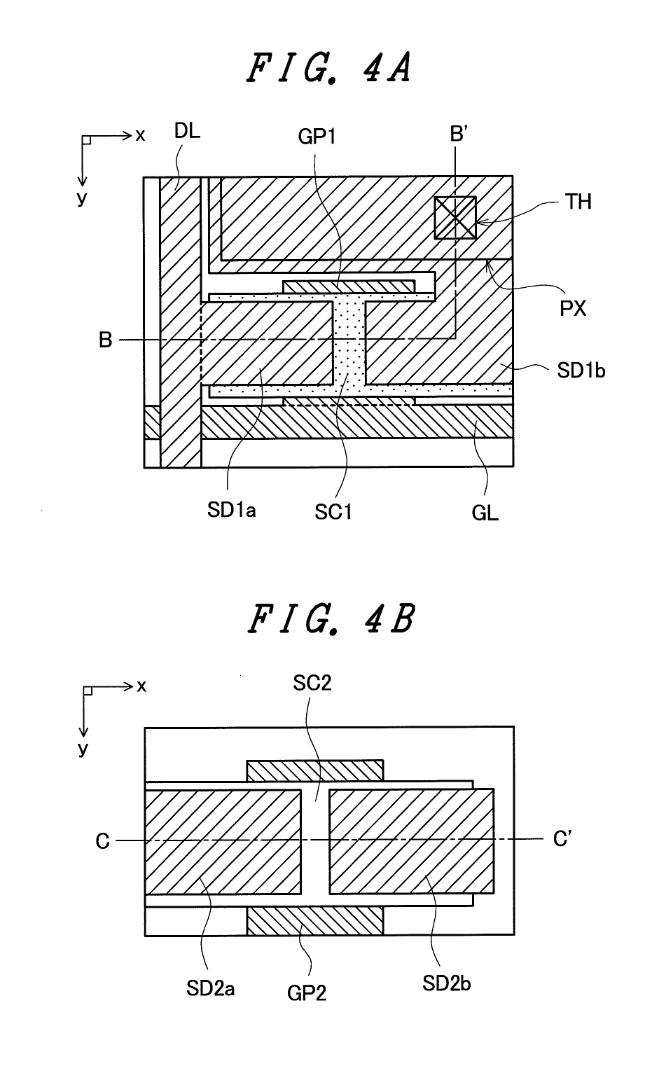

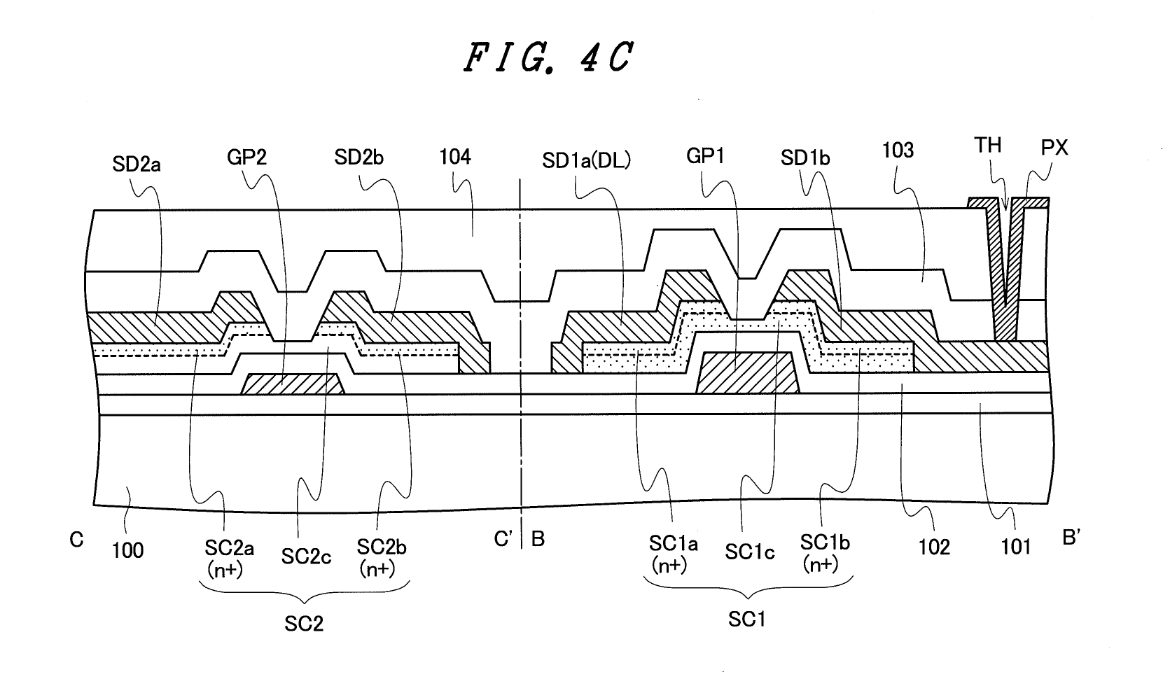

FIG. 4A to FIG. 4C are schematic views for explaining the summary of the present invention.

FIG. 4A is a schematic plan view showing one example of the schematic constitution of the TFT element in the display region of the TFT substrate to which the present invention is applied. FIG. 4B is a schematic plan view showing one example of the schematic constitution of the MOS transistor of a peripheral circuit of the TFT substrate to which the present invention is applied. FIG. 4C is a schematic cross-sectional view showing one example of the cross-sectional constitution of the TFT substrate taken along a line B-B′ in FIG. 4A and one example of the cross-sectional constitution of the TFT substrate taken along a line C-C′ in FIG. 4B in a juxtaposed manner. Here, in FIG. 4C, (n+) indicates an n-type impurity region of high concentration.

The present invention is applicable to a case in which the TFT substrate 1 having the constitution shown in FIG. 2 and FIG. 3 is configured such that the TFT elements (MOS transistors) in the display region DA and the MOS transistors in the peripheral region adopt the so-called bottom gate structure, that is, the TFT elements (MOS transistors) form gate electrodes of respective transistors between the substrate such as the glass substrate and the semiconductor layers.

Here, the MOS transistor (TFT element) which is arranged in each pixel in the display region DA is configured as shown in FIG. 4A and FIG. 4C, wherein a gate electrode GP1 is formed on a background insulation layer 101 formed on a surface of the glass substrate 100. The gate electrode GP1 is, for example, integrally formed with the scanning signal line GL and is formed by making use of a rectangular projecting portion of the scanning signal line GL which is formed by partially increasing a width (size in the y direction) of the scanning signal line GL.

Further, as viewed from the glass substrate 100, on the gate electrode GP1, a semiconductor layer SC1 is formed by way of a first insulation layer 102 having a function of a gate insulation film of the TFT element. The semiconductor layer SC1 is constituted of three regions consisting of a drain region SC1a, a source region SC1b and a channel region SC1c. All three regions are formed of an amorphous semiconductor such as amorphous silicon. When the TFT element is an N-channel MOS transistor, the drain region SC1a and the source region SC1b of the semiconductor layer SC1 are formed of an n-type amorphous semiconductor in which P⁺ (phosphorus ion) is implanted as impurities. Further, when the TFT element is an N-channel MOS transistor, the channel region SC1c is formed of any one of an intrinsic (i-type) amorphous semiconductor, an n-type amorphous semiconductor of extremely low impurity concentration and a p-type amorphous semiconductor of extremely low impurity concentration.

Further, as viewed from the glass substrate 100, a drain electrode SD1a is formed on the drain region SC1a of the semiconductor layer SC1, and a source electrode SD1b is formed on the source region SC1b of the semiconductor layer SC1. The drain electrode SD1a is, for example, integrally formed with the video signal line DL and is formed by making use of a rectangular projecting portion of the video signal line DL by partially increasing a width (size in the x direction) of the video signal line DL.

Further, as viewed from the glass substrate 100, on the drain electrode SD1a, the source electrode SD1b and the like, the pixel electrode PX is formed by way of a second insulation layer 103 and a third insulation layer 104. The pixel electrode PX is connected with the source electrode SD1b via a through hole TH.

Here, the MOS transistor in the peripheral region, for example, the MOS transistor of the first drive circuit DRV1 is configured as shown in FIG. 4B and FIG. 4C, wherein the gate electrode GP2 is formed on the background insulation layer 101 formed on a surface of the glass substrate 100. Here, in the TFT substrate 1 to which the present invention is applied, a thickness of the gate electrode GP2 of the MOS transistor in the peripheral region is set smaller than a thickness of the gate electrode GP1 of the TFT element in the display region DA.

Further, as viewed from the glass substrate 100, on the gate electrode GP2, a semiconductor layer SC2 is formed by way of a first insulation layer 102. The semiconductor layer SC2 is constituted of three regions consisting of a drain region SC2a, a source region SC2b and a channel region SC2c. The drain region SC2a and the source region SC2b are formed of an amorphous semiconductor such as amorphous silicon, and the channel region SC2c is formed of a polycrystalline semiconductor such as polycrystalline silicon. When the MOS transistor in the peripheral region is an N-channel MOS transistor, the drain region SC2a and the source region SC2b of the semiconductor layer SC2 are formed of an n-type amorphous semiconductor in which P⁺ (phosphorus ion) is implanted as impurities. Further, when the MOS transistor in the peripheral region is an N-channel MOS transistor, the channel region SC2c is formed of any one of an intrinsic (i-type) polycrystalline semiconductor, an n-type polycrystalline semiconductor of extremely low impurity concentration and a p-type polycrystalline semiconductor of extremely low impurity concentration. Particularly, when the channel region SC2c of the semiconductor layer SC2 is formed of polycrystalline silicon, a threshold value of the MOS transistor can be controlled by slightly adding impurities to the channel region SC2c.

Further, as viewed from the glass substrate 100, a drain electrode SD2a is formed on the drain region SC2a of the semiconductor layer SC2, and a source electrode SD2b is formed on the source region SC2b.

Further, as viewed from the glass substrate 100, on the drain electrode SD2a and the source electrode SD2b, the second insulation layer 103 and the third insulation layer 104 are formed.

The present invention is, as described above, applicable to the case in which the TFT elements (MOS transistors) in the display region DA (first region) and the MOS transistors in the peripheral region (second region) respectively adopt the bottom gate structure which includes the gate electrode between the glass substrate and the semiconductor layer, the respective regions of the semiconductor layers SC1 of the MOS transistors in the display region DA are formed of the amorphous semiconductor such as amorphous silicon, and the channel regions SC2c of the semiconductor layers SC2 of the MOS transistors in the peripheral region are formed of polycrystalline semiconductor such as polycrystalline silicon.

Hereinafter, the explanation is made with respect to the constitution and the manufacturing method of the gate electrodes GP1, GP2 of the respective MOS transistors in the display region DA and the peripheral region SA of the TFT substrate 1 of the liquid crystal display device to which the present invention is applied.

### Embodiment 1

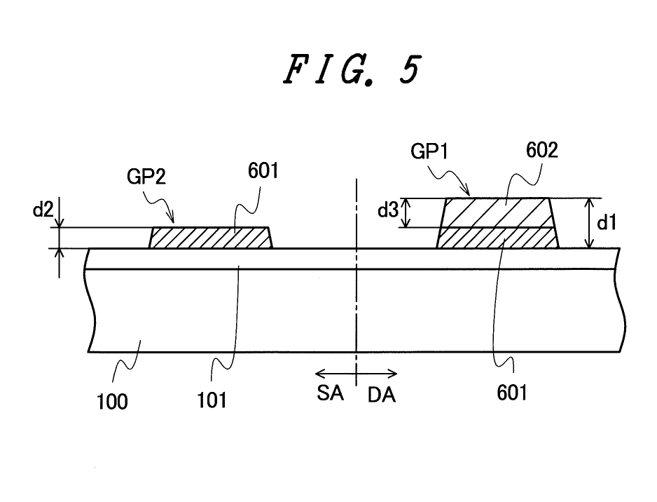

FIG. 5 is a schematic cross-sectional view showing a constitutional feature of a TFT substrate of an embodiment 1 according to the present invention. Here, in FIG. 5, a right side of a chained line shows one example of the cross-sectional constitution of the gate electrode GP1 of the TFT element (MOS transistor) formed in the display region DA, while a left side of the chained line shows one example of the cross-sectional constitution of the gate electrode GP2 of the MOS transistor formed in the peripheral region SA.

In the TFT substrate 1 of the embodiment 1, for example, as shown in FIG. 5, a thickness d2 of the gate electrode GP2 of the MOS transistor of the first drive circuit DRV1 or the like arranged in the peripheral region SA is set smaller than a thickness d1 of the gate electrode GP1 of the TFT element in the display region DA. Here, the gate electrode GP1 of the TFT element in the display region DA is constituted by stacking the second conductive layer 602 having a thickness d3 on a first conductive layer 601 used for forming the gate electrode GP2 of the MOS transistor in the peripheral region SA.

In the embodiment 1, the first conductive layer 601 which is used for forming the gate electrode GP2 of the MOS transistor in the peripheral region SA and a lower layer of the gate electrode GP1 of the TFT element in the display region DA, and the second conductive layer 602 which is used only as the gate electrode GP1 of the TFT element in the display region DA may be formed of the same material or may be formed of materials different from each other. However, it is desirable to combine the material of the first conductive layer 601 and the material of the second conductive layer 602 such that heat conductivity of the material of the first conductive layer 601 is lower than heat conductivity of the material of the second conductive layer 602. Here, it is further desirable to combine the material of the first conductive layer 601 and the material of the second conductive layer 602 such that the electric resistance (wiring resistance) of the material of the second conductive layer 602 is lower than the electric resistance (wiring resistance) of the material of the first conductive layer 601.

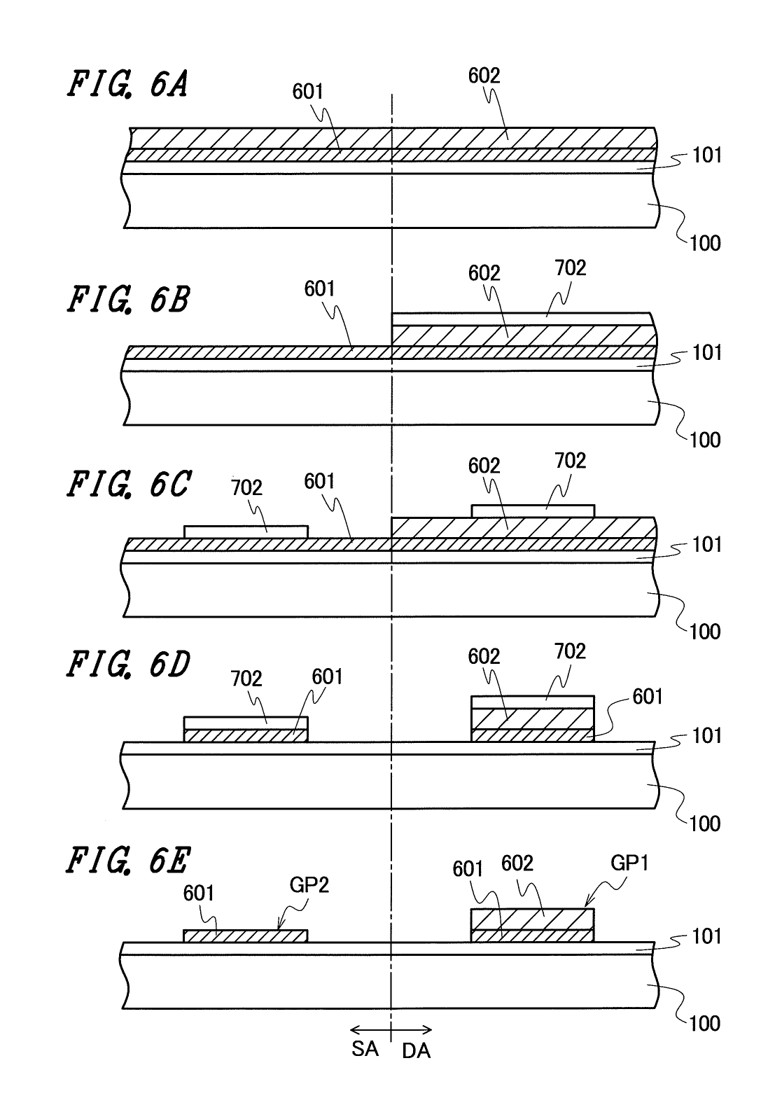

FIG. 6A to FIG. 6E are schematic cross-sectional views for explaining a manufacturing method of the gate electrodes of the TFT substrate of the embodiment 1. Here, FIG. 6A to FIG. 6E show only portions which characterize the manufacturing method in steps for forming the gate electrodes. Further, in FIG. 6A to FIG. 6E, a right side of a chained line shows steps for forming the gate electrode GP1 of the TFT element (MOS transistor) formed in the display region DA, while a left side of the chained line shows steps for forming the gate electrode GP2 of the MOS transistor formed in the peripheral region SA.

In the manufacturing method of the TFT substrate 1 of the embodiment 1, with respect to the steps for forming the gate electrode GP1 of the TFT element in the display region DA and the gate electrode GP2 of the MOS transistor in the peripheral region SA, first of all, as shown in FIG. 6A, a background insulation layer 101 formed of a silicon nitride film (an SiN film), for example, is formed on the glass substrate 100 (insulation substrate) and, thereafter, the first conductive layer 601 and the second conductive layer 602 are continuously formed.

Next, as shown in FIG. 6B, a resist 701 is formed on only the display region DA out of a top surface of the second conductive layer 602 and, thereafter, etching is performed using the resist 701 as a mask so as to remove the second conductive layer 602 provided outside the display region DA (the peripheral region SA or the like).

Next, after removal of the resist 701, as shown in FIG. 6C, another resists 702 are formed in a region where the gate electrode is formed in the display region DA and in a region where the gate electrode is formed in the peripheral region SA.

Next, as shown in FIG. 6D, etching is performed using resists 702 as masks so as to remove unnecessary portions of the second conductive layer 602 and the first conductive layer 601 in the display region DA and, at the same time, to remove unnecessary portions of the first conductive layer 601 in the peripheral region SA.

Thereafter, the resist 702 is removed. As a result, as shown in FIG. 6E, the gate electrode GP1 is formed in the display region DA in a state that the first conductive layer 601 and the second conductive layer 602 are stacked to each other, while the thin gate electrode GP2 which is formed of only the first conductive layer 601 is formed in the peripheral region SA.

Here, in forming the gate electrodes GP1, GP2 in accordance with the steps shown in FIG. 6A to FIG. 6E, although the first conductive layer 601 and the second conductive layer 602 may be formed of the same material, it is desirable to form the first conductive layer 601 and the second conductive layer 602 using materials different from each other. Particularly, the first conductive layer 601 used for forming the gate electrode GP2 of the MOS transistor in the peripheral region SA is subject to a high temperature in the step for forming polycrystalline silicon used for forming the channel region SC2c of the semiconductor layer SC2 and hence, it is desirable to use a high-melting-point metal material for forming the first conductive layer 601.

When the first conductive layer 601 and the second conductive layer 602 are formed of the same material, for example, an MoW alloy may be used as such a material. However, when the first conductive layer 601 and the second conductive layer 602 are formed of the same material, in the step shown in FIG. 6B, that is, in etching the second conductive layer 602 in the peripheral region SA, it is difficult to remove only the second conductive layer 602. Accordingly, there exists a possibility that a surface of the first conductive layer 601 is also etched thus giving rise to a possibility that the flatness of the gate electrode GP2 in the peripheral region SA is worsened.

In view of the above, it is desirable to form the first conductive layer 601 using, for example, a material having a melting point higher than a melting point of the second conductive layer 602 and having heat conductivity lower than heat conductivity of the second conductive layer 602. Further, it is desirable that the first conductive layer 601 is formed using a material which exhibits non-solubility or insolubility against an etchant which is used for etching the second conductive layer 602, for example. Still further, it is desirable that the first conductive layer 601 is formed using a material having electric conductivity lower than electric conductivity of the second conductive layer 602, for example. As the combination of the materials which satisfies such conditions, for example, the combination which uses any one of Ta, Ti (titanium) and MoW as the material of the first conductive layer 601, and Al (aluminum) as the material of the second conductive layer 602 is considered.

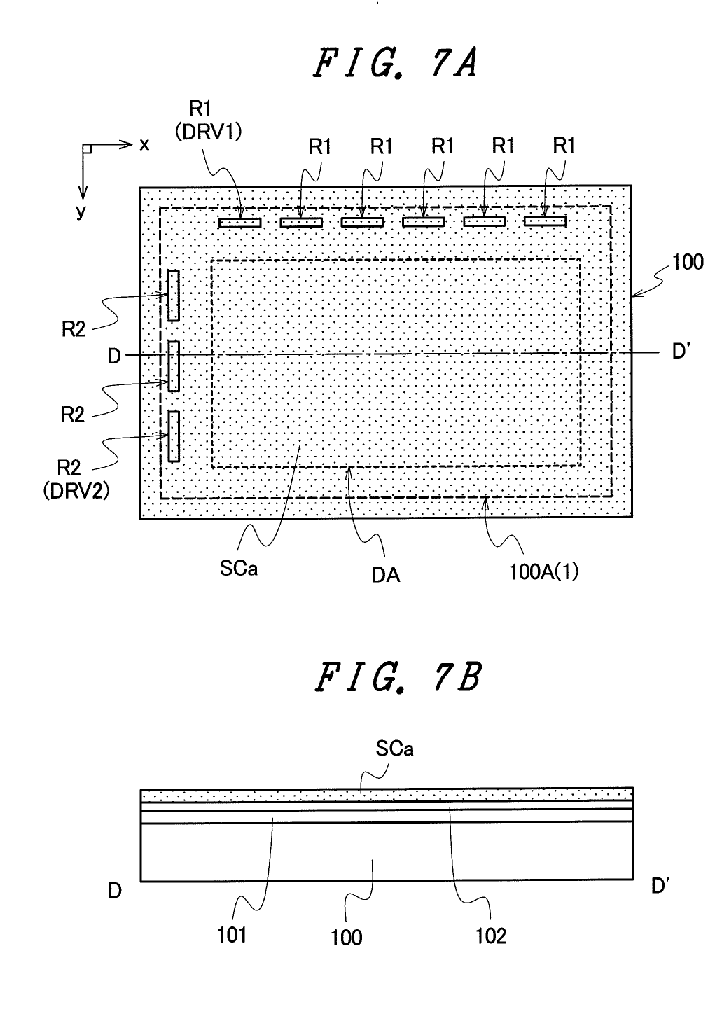

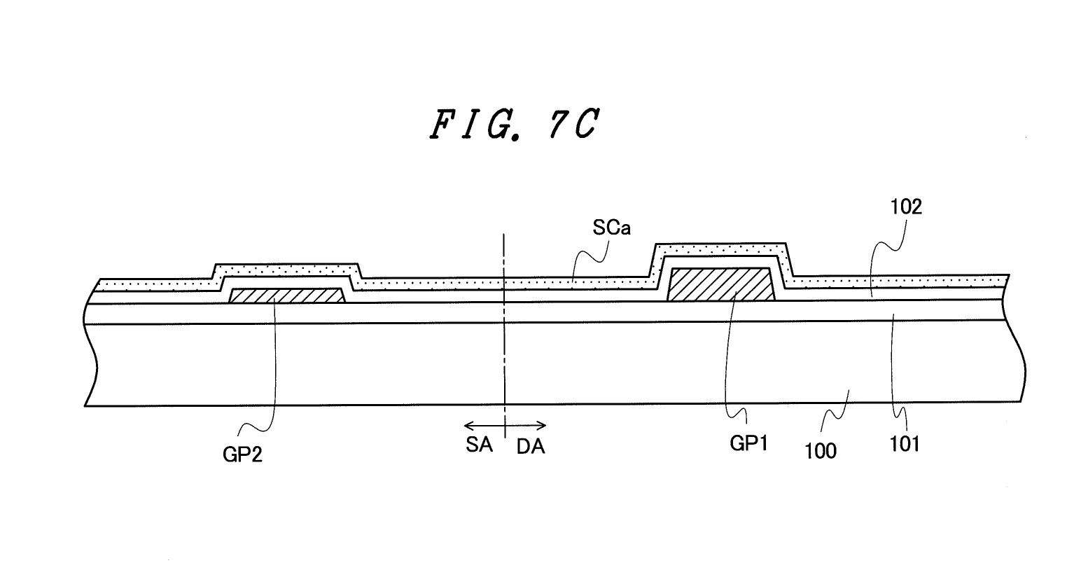

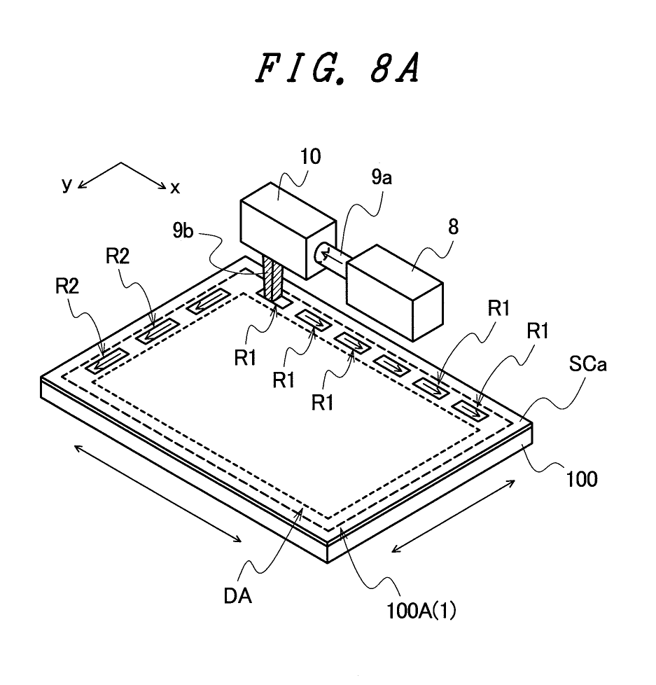

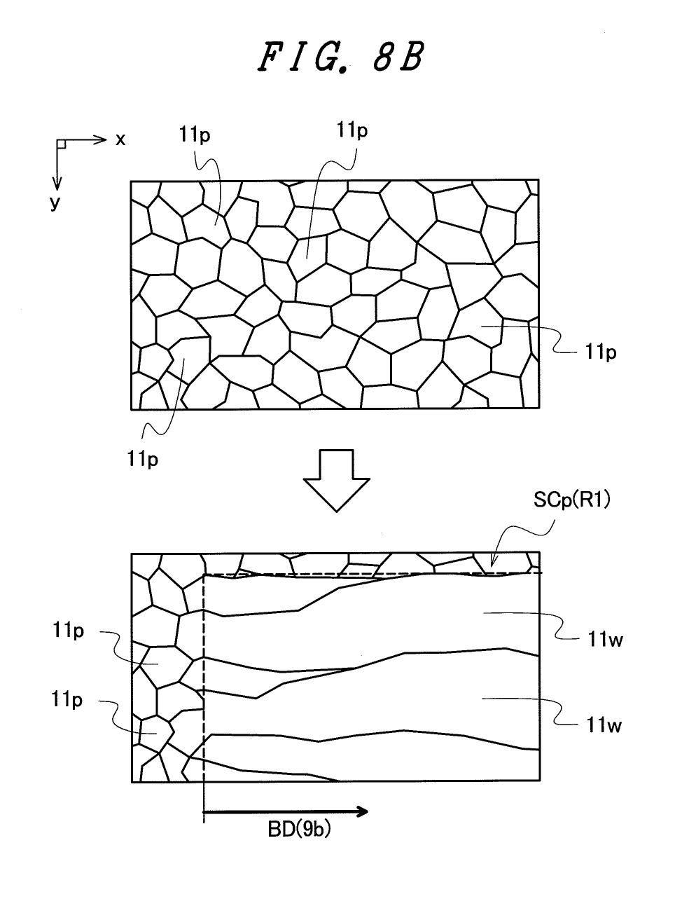

FIG. 7A to FIG. 7C, FIG. 8A and FIG. 8B are schematic views for explaining the manufacturing method of the semiconductor layer of the TFT substrate according to the embodiment 1.

FIG. 7A is a schematic plan view showing the schematic constitution of a substrate immediately after forming an amorphous silicon film. FIG. 7B is a schematic cross-sectional view of the substrate taken along a line D-D′ in FIG. 7A. FIG. 7C is a schematic cross-sectional view of the substrate showing a region where the gate electrode of the MOS transistor is formed in a peripheral region and a region where the gate electrode of the TFT element is formed in the display region in the cross-sectional view shown in FIG. 7B in an enlarged juxtaposed manner. FIG. 8A is a schematic perspective view showing one example of a method for reforming amorphous silicon into polycrystalline silicon. FIG. 8B is a schematic plan view showing the schematic constitution of a semiconductor layer in a region which is formed into polycrystalline silicon.

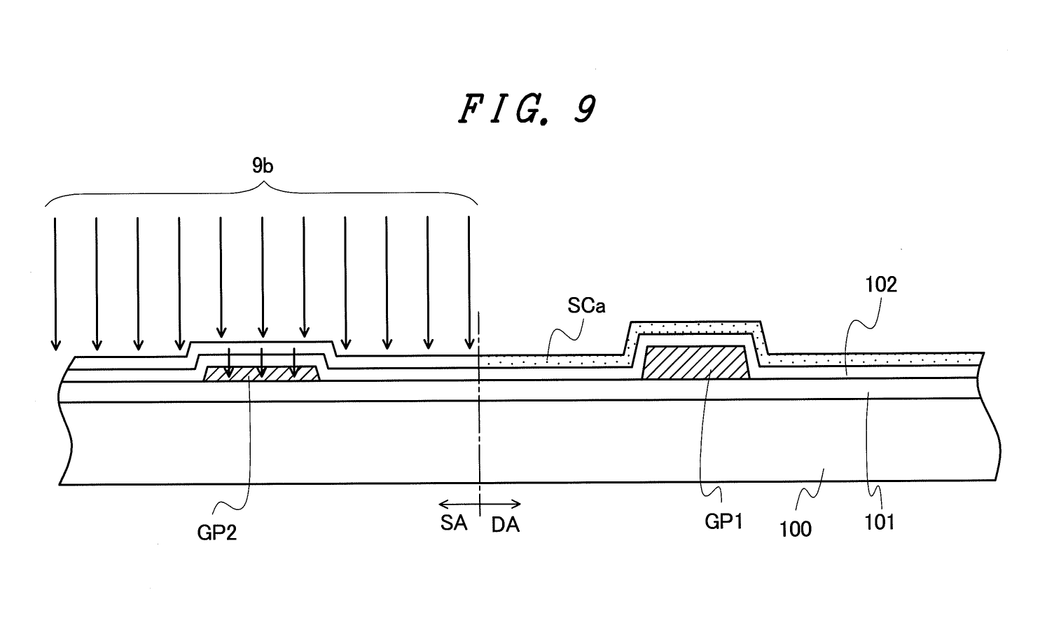

Here, in FIG. 7C and FIG. 9, a right side of a chained line shows one example of the cross-sectional constitution on a periphery of the gate electrode GP1 of the TFT element (MOS transistor) formed in the display region DA, while a left side of the chained line shows one example of the cross-sectional constitution on a periphery of the gate electrode GP2 of the MOS transistor formed in the peripheral region SA.

The glass substrate 100 used for manufacturing the liquid crystal display device (TFT substrate 1) of the embodiment 1 is manufactured using the glass substrate 100 which is referred to as a mother glass having a size larger than a size used as the TFT substrate 1, for example, as shown in FIG. 7A. The gate electrodes GP1, GP2 are formed on the mother glass 100 in accordance with the above-mentioned steps and, thereafter, sequentially, the first insulation layer 102, the semiconductor layers SC1, SC2, the video signal line DL (including the drain electrodes SD1a), the source electrodes SD1b, the pixel electrodes PX and the like are formed. Finally, by cutting the region 100A from the mother glass 100, it is possible to acquire the TFT substrate 1 having the constitution shown in FIG. 2 and FIG. 3.

After forming the gate electrodes GP1, GP2 in accordance with the above-mentioned steps, for example, as shown in FIG. 7A and FIG. 7B, the first insulation layer 102 having a function of a gate insulation film is formed on the whole surface of the mother glass 100 and, subsequently, the amorphous silicon film SCa is formed on the first insulation layer 102. Here, the amorphous silicon film SCa is formed on the whole surface of the mother glass 100 including the peripheral region SA besides the display region DA. Further, although not shown in FIG. 7B, in the display region DA, regions R1 in which the first drive circuits are formed and regions R2 in which the second drive circuits are formed out of the peripheral region SA, for example, as shown in FIG. 7C, the gate electrodes GP1, GP2, the scanning signal line GL and the like are formed. Accordingly, in the amorphous silicon film SCa, for example, in boundaries between portions of the amorphous silicon film SCa over the gate electrodes GP1, GP2 and portions of the amorphous silicon film SCa outside the gate electrodes GP1, GP2, stepped portions are formed corresponding to thicknesses of the respective gate electrodes GP1, GP2.

In the manufacturing method of the TFT substrate 1 of the embodiment 1, the amorphous silicon film SCa is formed and, thereafter, for example, the amorphous silicon film SCa in a whole area of the peripheral region SA or the regions R1 in which the first drive circuits are formed and the regions R2 in which the second drive circuits are formed is formed into polycrystalline silicon.

In forming the amorphous silicon film SCa into polycrystalline silicon, for example, energy beams of an excimer laser, a continuous oscillation laser or the like are radiated to the regions which are to be formed into polycrystalline silicon so as to melt the amorphous silicon film SCa and, thereafter, molten silicon is crystallized. To be more specific, first of all, the energy beams of the excimer laser, a continuous oscillation laser or the like are radiated to the regions to be formed into polycrystalline silicon so as to dehydrogenate the amorphous silicon film SCa. Then, the energy beams of another laser or the like are radiated to the dehydrogenated amorphous silicon film so as to melt the amorphous silicon film SCa and, thereafter, the amorphous silicon film SCa is crystallized. Here, the mother glass 100 is fixedly mounted on a stage which is movable in the x direction as well as in the y direction, for example. Then, for example, as shown in FIG. 8A, continuous oscillation laser beams 9a generated by the laser oscillator 8 are converted into the desired energy density and shape using an optical system 10, and the converted continuous oscillation laser beams 9b are radiated to the amorphous silicon SCa of the mother glass 100. Here, the radiation position of the continuous oscillation laser beams 9b on the mother glass 100 is moved by moving the stage which mounts the mother glass 100 thereon in the x direction as well as in the y direction thus radiating the continuous oscillation laser beams 9b to the whole area of the regions to be formed into polycrystalline silicon.

Here, to form molten silicon into polycrystalline silicon, for example, the energy density of the continuous oscillation laser beams 9b to be radiated and the moving speed (scanning speed) of the radiation region may be adjusted. When the energy density of the continuous oscillation laser beams 9b to be radiated and the moving speed (scanning speed) of the radiation region satisfy predetermined conditions, a lateral growth occurs in a process that molten silicon is solidified leading to the acquisition of polycrystalline silicon which is a mass of strip-like crystals extending along the moving direction of the radiation region in an elongated manner.

Further, in forming the amorphous silicon film SCa into polycrystalline silicon, for example, first of all, as shown on an upper side of FIG. 8B, polycrystalline silicon which is a mass of minute crystals lip such as fine crystals or granular crystals may be formed. In this case, the continuous oscillation laser beams 9b are again radiated to polycrystalline silicon which is a mass of minute crystals 11p so as to melt and recrystalize polycrystalline silicon thus forming, as shown on a lower side of FIG. 8B, polycrystalline silicon SCp which is a mass of strip-like crystals 11w extending along the moving direction BD of the radiation position of the continuous oscillation laser beams 9b in an elongated manner.

In forming polycrystalline silicon SCp which is a mass of such strip-like crystals 11w, by forming the drain electrode SD2a and the source electrode SD2b such that the direction along which the strip-like crystals 11w extend in an elongated manner assumes the channel length direction, that is, a carrier moving direction in the MOS transistor, grain boundaries which impede the movement of the carrier are hardly generated thus realizing a high-speed operation of the MOS transistors of the respective drive circuits DRV1, DRV2.

A manufacturing method (steps) of the TFT substrate after forming the amorphous silicon film SCa in the peripheral region SA into polycrystalline silicon SCp in accordance with the above-mentioned steps is simply explained hereinafter.

After forming the amorphous silicon film SCa in the peripheral region SA into polycrystalline silicon SCp, subsequently, for example, an n-type amorphous silicon film is formed on the whole surface of the mother glass 100, and the n-type amorphous silicon film, the amorphous silicon film SCa and polycrystalline silicon SCp are patterned in an island shape.

Next, a conductive film is formed on the whole surface of the mother glass 100, and the conductive film is patterned to form the video signal lines DL, the drain electrodes SD1a, SD2a, the source electrodes SD1b, SD2b and the like.

Next, while using the drain electrodes SD1a, SD2a and the source electrodes SD1b, SD2b as masks, the n-type amorphous silicon film formed on the amorphous silicon film SCa and the polycrystalline silicon film SCp is etched. Here, the n-type amorphous silicon film formed on the amorphous silicon film SCa is separated into the drain regions SC1a and the source regions SC1b, while the n-type amorphous silicon film formed on the polycrystalline silicon film SCp is separated into the drain regions SC2a and the source regions SC2b. Further, when the n-type amorphous silicon film is etched, for example, as shown in FIG. 4C, the amorphous silicon film SCa and the polycrystalline silicon SCp are also partially removed and hence, thicknesses of these films are decreased. By forming the semiconductor layers in accordance with such steps, the semiconductor layer SC1 of the TFT element in the display region DA is constituted of a semiconductor layer in which all of the drain region SC1a, the source region SC1b and the channel region SC1c are formed of amorphous silicon. On the other hand, the semiconductor layer SC2 of the MOS transistor in the peripheral region SA is constituted of a semiconductor layer in which the drain region SC2a and the source region SC2b are formed of amorphous silicon and the channel region SC1c is formed of polycrystalline silicon.

Thereafter, a second insulation layer 103 and a third insulation layer 104 are formed. After forming through holes TH in the second insulation layer 103 and the third insulation layer 104, for example, a conductive film having high optical transmissivity such as an ITO film is formed, and the conductive film (ITO film) is patterned to form the pixel electrodes PX.

FIG. 9 is a schematic cross-sectional view for explaining the manner of operation and advantageous effects of the manufacturing method of the TFT substrate of the embodiment 1.

In the above-mentioned steps for forming the amorphous silicon film SCa into polycrystalline silicon, for example, it is necessary to heat and melt the amorphous silicon film SCa by radiating the energy beams of the continuous oscillation laser to the amorphous silicon film SCa. Here, for example, when the energy beams of the continuous oscillation laser are radiated to the amorphous silicon film SCa in the peripheral region SA, as shown in FIG. 9, for example, heat generated by the energy beams radiated to amorphous silicon SCa on the gate electrode GP2 in the peripheral region SA is transferred to the gate electrode GP2 by way of the first insulation film 102. Here, a total heat value (energy) which amorphous silicon SCa receives differs between a portion over the gate electrode GP2 and a portion outside the gate electrode GP2 thus giving rise to a possibility of irregularities in crystallinity. Accordingly, as in the case of the manufacturing method of the TFT substrate 1 of the embodiment 1, by decreasing a heat conduction quantity by forming the gate electrode GP2 in the region to which laser beams are radiated (region to be formed into polycrystalline silicon) while decreasing a thickness of the gate electrode GP2, the difference in the total heat value which the amorphous silicon film SCa receives between the portion over the gate electrode GP2 and the portion outside the gate electrode GP2 can be decreased thus reducing irregularities of crystallinity. This crystallinity irregularity reduction effect can be increased corresponding to lowering of heat conductivity of the first conductive layer 601 which is used for forming the gate electrode GP2, and also is increased corresponding to the reduction of the film thickness.

Further, as in the case of the manufacturing method of the TFT substrate 1 of the embodiment 1, by forming the gate electrode GP2 in the region to which laser beams are radiated (region to be formed into polycrystalline silicon) while decreasing a thickness of the gate electrode GP2, it is possible to decrease (lower) a stepped portion of amorphous silicon film SCa which is formed in a boundary between the portion over the gate electrode GP2 and the portion outside the gate electrode GP2. Accordingly, when the amorphous silicon film SCa is melt by radiating laser beams, a quantity of molten silicon which flows down from an upper portion to a lower portion of the stepped portion can be reduced thus reducing peeling-off of the film at the stepped portion. This advantageous effect can be increased corresponding to the reduction of a film thickness of the first conductive layer 601 used in forming the gate electrode GP2.

Further, in the manufacturing method of the TFT substrate of the embodiment 1, it is possible to reduce only the thickness of the gate electrodes GP2 of the MOS transistors in the regions to be radiated with the laser beams, that is, the regions R1 where the first drive circuit DRV1 in which a high-speed operation is required is formed and the regions R2 where the second drive circuit DRV2 in which a high-speed operation is required is formed, while the gate electrodes GP1 of the TFT element in the display region DA can have the substantially equal thickness as the gate electrodes in a conventional liquid crystal display device (TFT substrate). Accordingly, for example, in forming the scanning signal lines GL which are integral with the gate electrodes GP1, it is possible to prevent the increase of the wiring resistance of the scanning signal lines GL thus reducing the increase of the power consumption and operational failures attributed to the delay of signals to the pixel portions. Although one end of the scanning signal line GL extends to the region R2 which is arranged outside the display region DA and in which the second drive circuit DRV2 is formed, a wiring length of a portion of the scanning signal line GL which passes the display region DA is longer than a wiring length of the scanning signal line GL outside the display region DA. Accordingly, by allowing the portion of the scanning signal line GL which passes the display region DA to have the same stacked-layer constitution as the gate electrode GP1, it is possible to increase the wiring resistance reducing effect. Here, although the wiring resistance reducing effect can be obtained even when the first conductive layer 601 and the second conductive layer 602 are formed of the same material, by forming the second conductive layer 602 using a material having electric conductivity higher than electric conductivity of the material for forming the first conductive layer 601, the wiring resistance reducing effect can be further enhanced. Further, the second conductive layer 602 may be formed of a material having a melting point lower than a melting point of the material for forming the first conductive layer 601. For example, the second conductive layer 602 may be formed using Al.

Further, in the manufacturing method of the TFT substrate of the embodiment 1, even when the film thicknesses of the gate insulation films 102 of the TFT element (MOS transistor) in the display region DA and the MOS transistor in the peripheral region SA are not increased, it is possible to reduce irregularities of crystallinity of the polycrystalline silicon film attributed to the influence of heat conductivity of the gate electrode GP2. Accordingly, other drawbacks which are caused by increasing a film thickness of the gate insulation film, for example, drawbacks such as lowering of ION and the increase of the irregularity of Vₜₕ among transistor characteristic or the drawback such as lowering of productivity can be obviated.

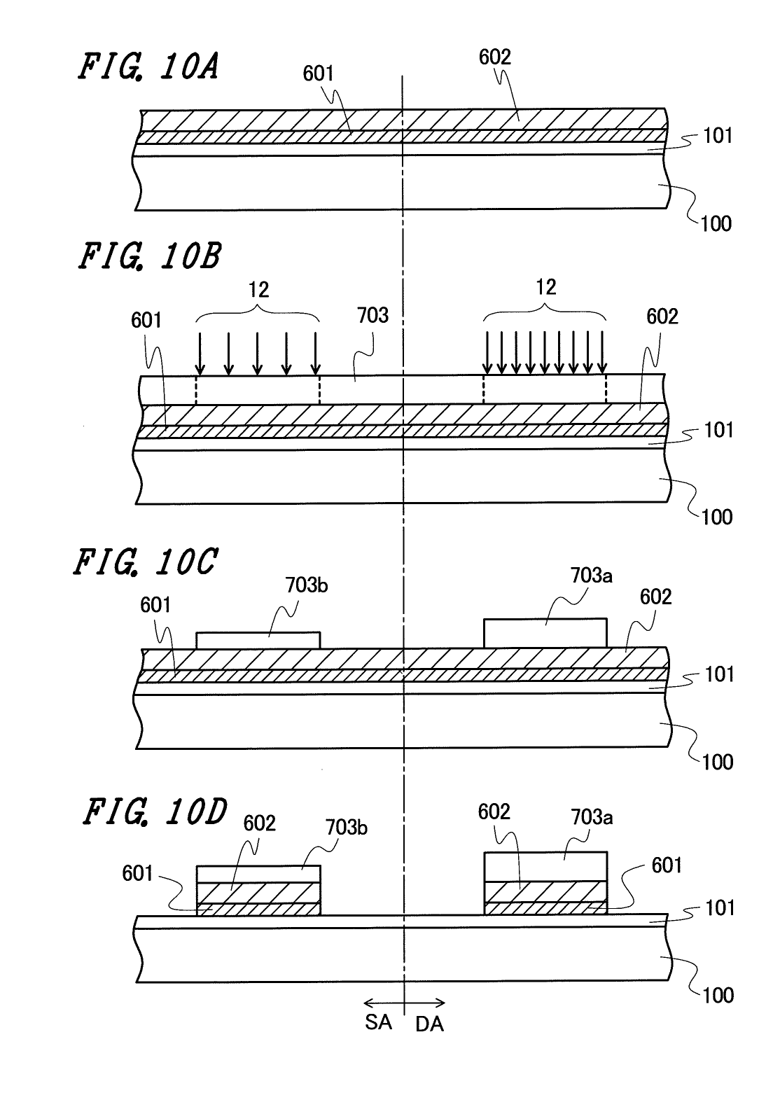

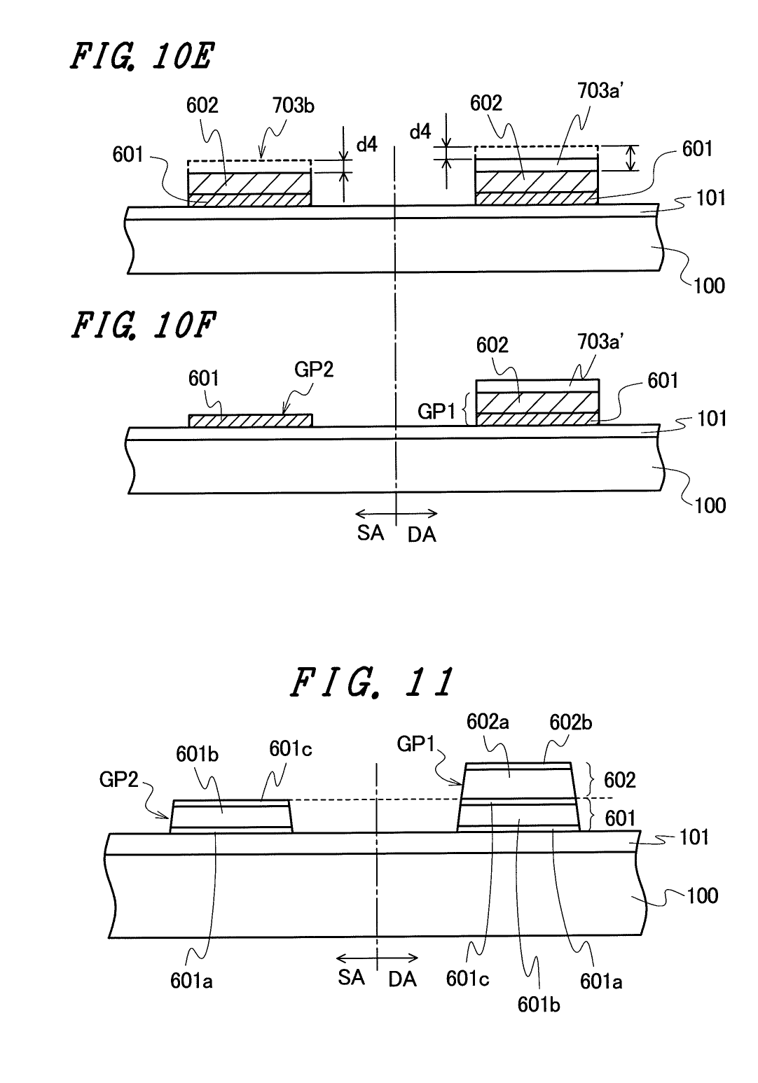

FIG. 10A to FIG. 10F are schematic cross-sectional views for explaining a modification of the manufacturing method of the TFT substrate of the embodiment 1. Here, FIG. 10A to FIG. 10F show only portions which characterize the manufacturing method in steps for forming the gate electrodes. Further, in FIG. 10A to FIG. 10F, a right side of a chained line shows steps for forming the gate electrode GP1 of the TFT element (MOS transistor) formed in the display region DA, while a left side of the chained line shows steps for forming the gate electrode GP2 of the MOS transistor formed in the peripheral region SA.

In the manufacturing method of the TFT substrate in the embodiment 1, as the steps for forming the gate electrodes GP1, GP2, for example, as shown in FIG. 6A to FIG. 6E, considered are steps in which the second conductive layer 602 formed outside the display region DA is removed using the first resist 701, and the gate electrodes GP1, GP2 are patterned using the second resist 702. However, in such steps, it is necessary to perform exposure and development using respectively different masks at the time of forming the first resist 701 and at the time of forming the second resist 702 and hence, the productivity is worsened. Accordingly, in forming the gate electrodes GP1, GP2 of the TFT substrate 1 of the embodiment 1, for example, it is desirable to form a resist using an exposure technique referred to as half exposure or half tone exposure and to perform removal of the second conductive layer 602 in the peripheral region SA and patterning of the gate electrodes GP1, GP2 using the resist which is formed with one-time exposure and one-time development.

Also in forming the gate electrodes GP1, GP2 by a half exposure technique which uses resists, first of all, as shown in FIG. 10A, the background insulation layer 101 formed of a silicon nitride film (an SiN film) or the like is formed on the glass substrate 100 (insulation substrate) and, thereafter, the first conductive layer 601 and the second conductive layer 602 are continuously formed.

Next, as shown in FIG. 10B, the half exposure is performed on a photosensitive resist 703 which is applied to the second conductive layer 602. In performing the half exposure, for example, with the use of a mask (not shown in the drawing) which sets a light transmitting quantity in the region where the thin gate electrode GP2 is formed in the peripheral region SA smaller than a light transmitting quantity in the region where the gate electrode GP1 is formed in the display region DA, quantities of lights 12 (for example, ultraviolet rays) which are radiated to the respective regions are changed. Here, for example, by finishing the exposure with a minimum time in which the resist 703 in the region where the gate electrode GP1 is formed in the display region DA is completely exposed, the resist 703 in the region where the thin gate electrode GP2 is formed in the peripheral region SA finishes the exposure thereof in an incomplete state. Accordingly, when the resist 703 is developed, for example, as shown in FIG. 10C, a film thickness of the resist 703b in the region where the thin gate electrode GP2 is formed in the peripheral region SA becomes smaller than the film thickness of the resist 703a in the region where the gate electrode GP1 is formed in the display region DA.

Here, in the steps shown in FIG. 10B and FIG. 10C, the case in which the resists 703a, 703b are formed using the negative photosensitive resist is exemplified. However, the present invention is not limited to such steps. For example, the resists 703a, 703b may be formed using a positive photosensitive resist.

Next, as shown in FIG. 10D, using the resist 703a in the region where the gate electrode GP1 is formed in the display region DA and the resist 703b in the region where the thin gate electrode GP2 is formed in the peripheral region SA as masks, unnecessary portions of the second conductive layer 602 and the first conductive layer 601 in the respective regions are removed. Here, although the thin gate electrode in the peripheral region SA has the same pattern as the final gate electrode GP2 with respect to a shape as viewed in a plan view, the second conductive layer 602 (unnecessary conductive layer) still remains.

Accordingly, subsequently, O₂ ashing is performed, for example. Due to such O₂ ashing, as shown in FIG. 10E, all resists 703a, 703b formed on the mother glass 100 are made thin by an amount corresponding to a thickness d4 of the resists 703b in the portions where the thin gate electrodes GP2 are formed in the peripheral region SA. Due to such a constitution, the portions where the thin gate electrodes GP2 are formed in the peripheral region SA have no resists, and the resists 703a′ which are made thin by an amount corresponding to the thickness d4 of the resists 703b remain only at portions where the gate electrodes GP1 are formed in the display region DA.

Next, for example, as shown in FIG. 10F, by removing the second conductive layer 602 by etching using the resists 703a′ which remain after O₂ ashing as masks, it is possible to form the thin gate electrodes GP2 formed of only the first conductive layer 601 in the peripheral region SA.

In this manner, with the use of the half tone exposure technique, the number of steps for exposing and developing the resists for forming the gate electrodes GP1, GP2 which differ in thickness can be set to one time.

FIG. 11 is a schematic cross-sectional view for explaining a variation of the TFT substrate of the embodiment 1. Here, in FIG. 11, a right side of a chained line shows the cross-sectional constitution of the gate electrode GP1 of the TFT element (MOS transistor) formed in the display region DA, while a left side of the chained line shows the cross-sectional constitution of the gate electrode GP2 of the MOS transistor formed in the peripheral region SA.

In the embodiment 1, the case in which the first conductive layer 601 and the second conductive layer 602 are respectively formed of the same material is exemplified, for example. However, the present invention is not limited to such a case and either one or both of the first conductive layer 601 and the second conductive layer 602 may be constituted by stacking two or more conductive layers. That is, with respect to the gate electrode GP2 in the peripheral region SA which is formed of only the first conductive layer 601, the first conductive layer 601 may be formed by stacking three conductive layers 601a, 601b, 601c as shown in FIG. 11, for example. Here, the gate electrode GP1 in the display region DA which is formed of the first conductive layer 601 and the second conductive layer 602 may be constituted such that, for example, as shown in FIG. 11, the second conductive layer 602 which is constituted of two conductive layers 602a, 602b may be stacked on the first conductive layer 601 which is constituted of three conductive layers 601a, 601b, 601c. In such a constitution, for example, the conductive layers 601b, 602a may be formed using Al and the conductive layers 601a, 601c, 602b may be formed using Mo or an MoW alloy.

Here, the example shown in FIG. 11 is one example of the combination of the stacked structure of the first conductive layer 601 and the stacked structure of the second conductive layer 602. Provided that the relationship between the electric properties and the thermal properties with respect to the gate electrodes GP1 in the display region DA, the gate electrodes GP2 in the peripheral region SA and the scanning signal lines GL satisfies the conditions explained in conjunction with the embodiment 1, it is needless to say that, the present invention may adopt other stacked constitutions.

### Embodiment 2

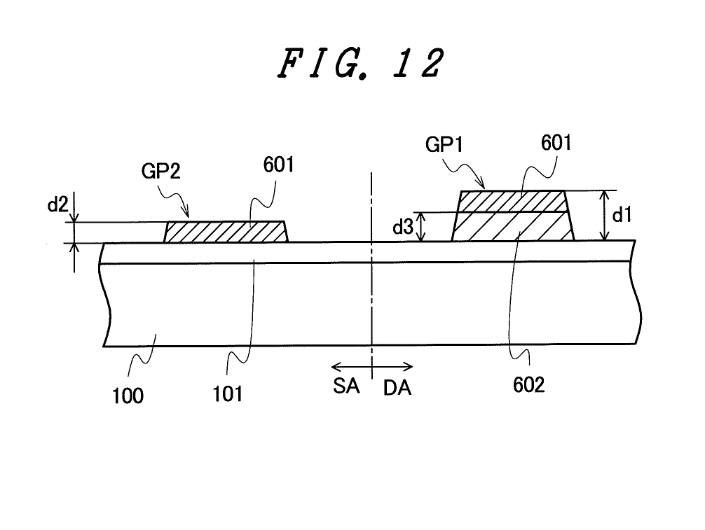

FIG. 12 is a schematic cross-sectional view showing a constitutional feature of a TFT substrate of an embodiment 2 according to the present invention. Here, in FIG. 12, a right side of a chained line shows one example of the cross-sectional constitution of the gate electrode GP1 of the TFT element (MOS transistor) formed in the display region DA, while a left side of the chained line shows one example of the cross-sectional constitution of the gate electrode GP2 of the MOS transistor formed in the peripheral region SA.

In the TFT substrate 1 of the embodiment 2, for example, as shown in FIG. 12, a thickness d2 of the gate electrode GP2 of the MOS transistor of the first drive circuit DRV1 or the like arranged in the peripheral region SA is set smaller than a thickness d1 of the gate electrode GP1 of the TFT element in the display region DA. Here, the TFT substrate 1 of the embodiment 2 is equal to the TFT substrate 1 of the embodiment 1 with respect to a point that the gate electrode GP2 in the peripheral region SA is formed of only the first conductive layer 601 and the gate electrode GP1 in the display region DA is formed of the first conductive layer 601 and the second conductive layer 602.

However, in the TFT substrate 1 of the embodiment 2, the gate electrode GP1 in the display region DA is configured such that the second conductive layer 602 is interposed between the glass substrate 100 (background insulation layer 101) and the first conductive layer 601.

Further, also in the embodiment 2, the first conductive layer 601 which is used for forming the gate electrode GP2 of the MOS transistor in the peripheral region SA and the gate electrode GP1 of the TFT element in the display region DA, and the second conductive layer 602 which is used only as the gate electrode GP1 of the TFT element in the display region DA may be formed of the same material or may be formed of materials different from each other. However, it is desirable to combine the material of the first conductive layer 601 and the material of the second conductive layer 602 such that, as also explained in conjunction with the embodiment 1, heat conductivity of the first conductive layer 601 is lower than heat conductivity of the second conductive layer 602. Here, it is further desirable to combine the material of the first conductive layer 601 and the material of the second conductive layer 602 such that the electric resistance (wiring resistance) of the second conductive layer 602 is lower than the electric resistance (wiring resistance) of the first conductive layer 601.

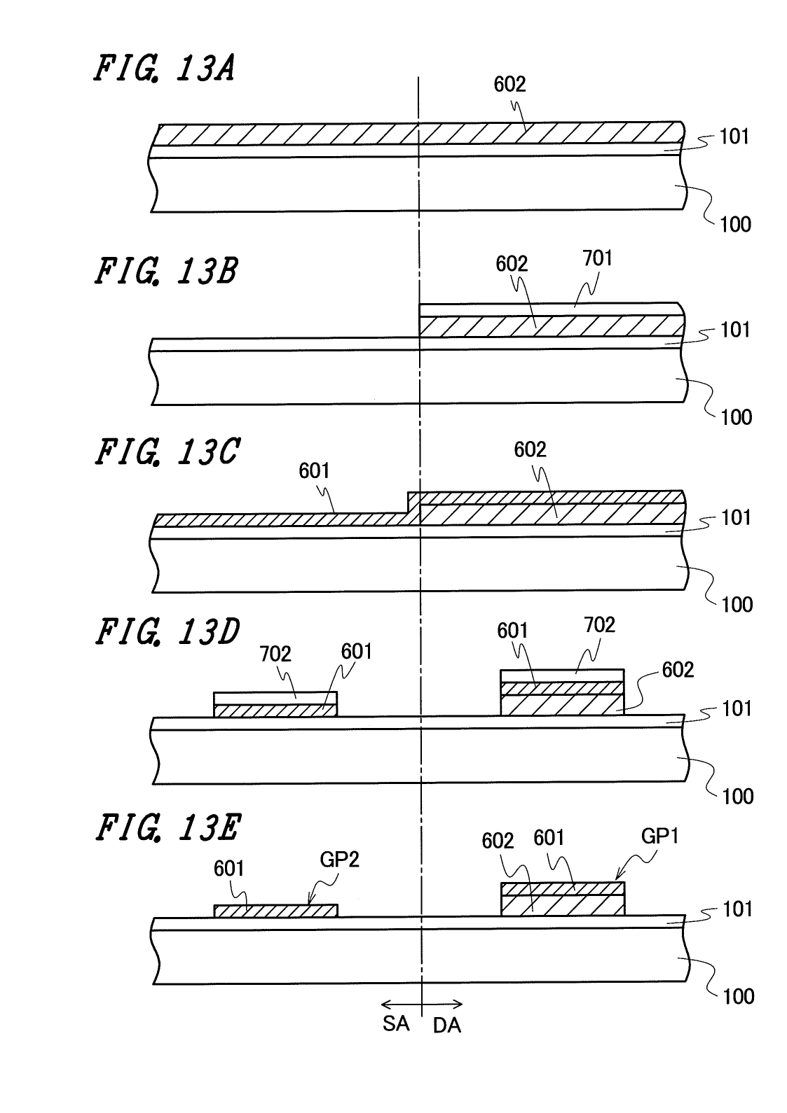

FIG. 13A to FIG. 13E are schematic cross-sectional views for explaining a manufacturing method of the gate electrodes of the TFT substrate of the embodiment 2. Here, FIG. 13A to FIG. 13E show only portions which characterize the manufacturing method in steps for forming the gate electrodes. Further, in FIG. 13A to FIG. 13E, a right side of a chained line shows steps for forming the gate electrode GP1 of the TFT element (MOS transistor) formed in the display region DA, while a left side of the chained line shows steps for forming the gate electrode GP2 of the MOS transistor formed in the peripheral region SA.

In the manufacturing method of the TFT substrate 1 of the embodiment 2, with respect to the steps for forming the gate electrodes GP1 of the TFT element in the display region DA, the gate electrodes GP2 of the MOS transistors of the first drive circuit DRV1 and the second drive circuit DRV2, first of all, as shown in FIG. 13A, a background insulation layer 101 formed of a silicon nitride film (an SiN film) or the like is formed on the glass substrate (insulation substrate) 100 and, thereafter, the second conductive layer 602 is formed.

Next, as shown in FIG. 13B, a resist 701 is formed on only the display region DA out of a top surface of the second conductive layer 602, and etching is performed so as to remove the second conductive layer 602 provided outside the display region DA (the peripheral region SA).

Next, after removal of the resist 701, as shown in FIG. 13C, the first conductive layer 601 is formed on the whole surface of the glass substrate 100, that is, on the display region DA and on the peripheral region SA.

Next, as shown in FIG. 13D, the resist 702 is formed on the first conductive film 601, and etching is performed using the resist 702 as a mask so as to remove unnecessary portions of the first conductive layer 601 and the second conductive layer 602 in the display region DA and, at the same time, to remove unnecessary portions of the first conductive layer 601 in the peripheral region SA outside the display region DA.

Thereafter, the resist 702 is removed. As a result, as shown in FIG. 13E, the gate electrode GP1 is formed in the display region DA in a state that the first conductive layer 601 and the second conductive layer 602 are stacked to each other, while the thin gate electrode GP2 which is formed of only the first conductive layer 601 is formed in the peripheral region SA.

Here, in forming the gate electrodes GP1, GP2 in accordance with the steps shown in FIG. 13A to FIG. 13E, the second conductive layer 602 and the first conductive layer 601 may be formed of the same material, or may be formed of materials different from each other. When the first conductive layer 601 and the second conductive layer 602 are formed of the same material, for example, an MoW alloy is used. Further, when the first conductive layer 601 and the second conductive layer 602 are formed of the different materials, for example, the first conductive layer 601 which is also used for forming the gate electrode GP2 of the MOS transistor in the peripheral region SA is formed using an MoW alloy and the second conductive layer 602 is formed using Al.

Then, after forming the gate electrodes GP1, GP2 in the respective regions DA, SA in accordance with the above-mentioned steps such that the gate electrodes GP1, GP2 differ in thickness between the display region DA and the peripheral region SA outside the display region DA and, at the same time, a thickness of the gate electrode GP2 in the peripheral region SA is smaller than a thickness of the gate electrode GP1 in the display region DA, the amorphous silicon film SCa is formed, and amorphous silicon SCa in the peripheral region SA is formed into polycrystalline silicon, for example. The steps for forming the peripheral region SA into polycrystalline silicon and advantageous effects obtained by such steps are exactly equal to the corresponding steps and advantageous effects explained in conjunction with the embodiment 1. Further, steps after forming the amorphous silicon film SCa in the peripheral region SA into polycrystalline silicon may be performed with the steps explained in conjunction with the embodiment 1 and hence, their explanation is omitted.

In this manner, also in the manufacturing method of the TFT substrate 1 of the embodiment 2, in forming the amorphous silicon SCa in the region where the MOS transistor is formed in the peripheral region SA into polycrystalline silicon, it is possible to reduce the irregularities in crystallinity between the portion over the gate electrode GP2 and the portion outside the gate electrode GP2 and the peeling-off of the film at the stepped portion.

Further, this embodiment can prevent the increase of the wiring resistances of the gate electrodes GP1 of the TFT elements and the scanning signal lines GL in the display region DA and hence, it is possible to suppress the increase of power consumption and defects attributed to the delay of signals to the pixel portions.

Further, other drawbacks which are caused by increasing a film thickness of the gate insulation film 102 of the TFT element (MOS transistor) in the respective regions, for example, drawbacks such as lowering of I_{ON} and the increase of the irregularity of Vₜₕ among transistor characteristic or the drawback such as lowering of productivity can be obviated.

Further, in the manufacturing method of the TFT substrate 1 of the embodiment 2, the second conductive layer 602 is formed on only the display region DA and, thereafter, the first conductive layer 601 is formed on the whole surface of the second conductive layer 602 and hence, it is sufficient to etch only the first conductive layer 601 in the peripheral region SA. Accordingly, even when the second conductive layer 602 and the first conductive layer 601 are formed of the same material such as an MoW ally, for example, it is possible to prevent the worsening of the flatness of the surface of the gate electrode GP2 in the peripheral region SA.

Further, in the embodiment 2, the case in which the first conductive layer 601 and the second conductive layer 602 are respectively formed of the single material is exemplified, for example. However, the present invention is not limited to such a case and, it is needless to say that, either one of or both of the first conductive layer 601 and the second conductive layer 602 may be configured by stacking two or more conductive layers.

### Embodiment 3

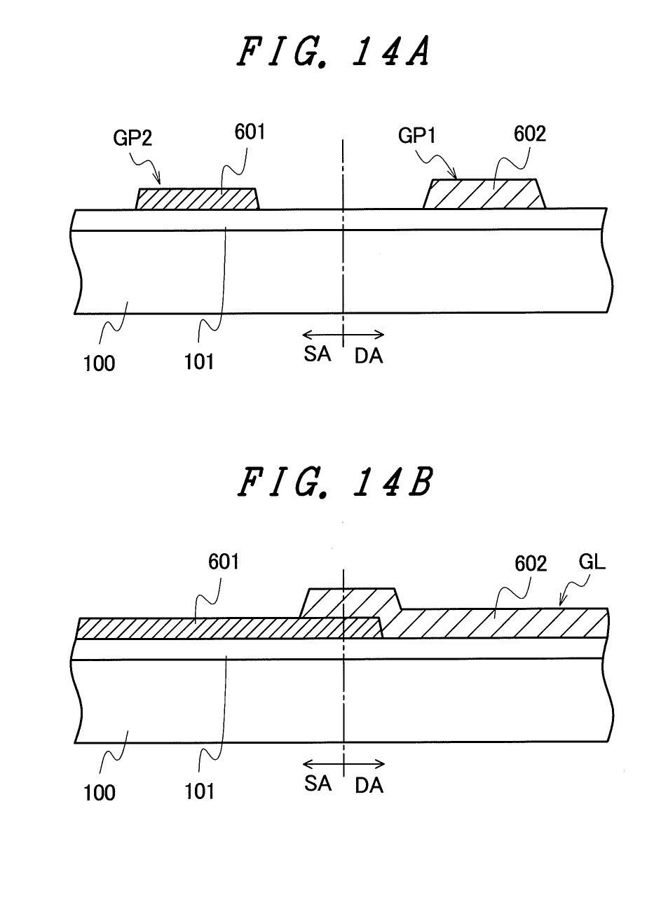

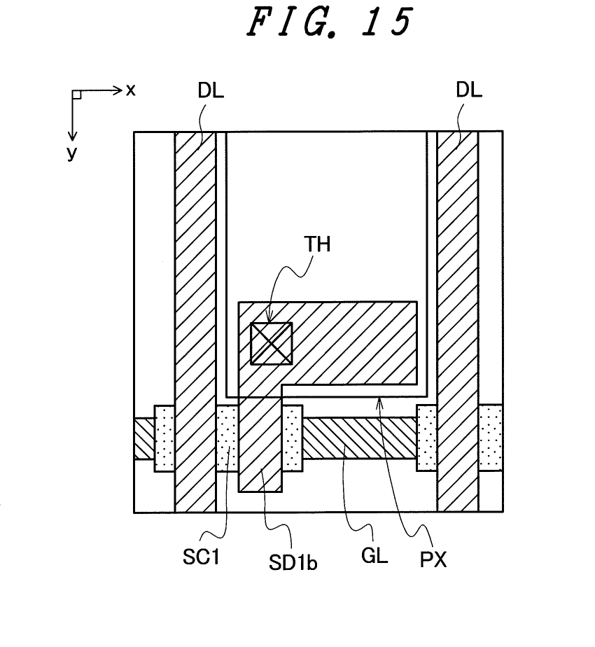

FIG. 14A and FIG. 14B are schematic cross-sectional views showing a constitutional feature of a TFT substrate of an embodiment 3 according to the present invention.

FIG. 14A is a schematic cross-sectional view showing one example of the cross-sectional constitution of the gate electrode in a display region and the gate electrode in a peripheral region. FIG. 14B is a schematic cross-sectional view showing one example of the cross-sectional constitution of a connecting portion between a scanning signal line in the display region and a scanning signal line in the peripheral region. Here, in FIG. 14A, a right side of a chained line shows one example of the cross-sectional constitution of the gate electrode GP1 of the TFT element (MOS transistor) formed in the display region DA, while a left side of the chained line shows one example of the cross-sectional constitution of the gate electrode GP2 of the MOS transistor formed in the peripheral region SA. Further, in FIG. 14B, a right side of a chained line shows one example of the cross-sectional constitution of the scanning signal line GL in the display region DA, while a left side of the chained line shows one example of the cross-sectional constitution of the scanning signal line GL in the peripheral region SA.

In the embodiment 1 and the embodiment 2, the explanation is made with respect to the constitution in which the gate electrode GP1 of the TFT element in the display region DA includes the first conductive layer 601 used in the gate electrode GP2 of the MOS transistor in the peripheral region SA. The constitution of the embodiment 3 differs from the constitutions of the embodiments 1 and 2, and the explanation is made with respect to the constitution in which the gate electrode GP1 of the TFT element in the display region DA does not include the first conductive layer 601 used for forming the gate electrode GP2 of the MOS transistor in the peripheral region SA.

In the TFT substrate 1 of the embodiment 3, for example, as shown in FIG. 14A, a thickness of the gate electrode GP2 of the MOS transistor of the first drive circuit DRV1 or the like arranged in the peripheral region SA is set smaller than a thickness of the gate electrode GP1 of the TFT element in the display region DA. Here, the TFT substrate 1 of the embodiment 3 is equal to the TFT substrate 1 of the embodiment 1 or the embodiment 2 with respect to a point that the gate electrode GP2 in the peripheral region SA is formed of only the first conductive layer 601.

However, in the TFT substrate 1 of the embodiment 3, the gate electrode GP1 of the TFT element in the display region DA is formed of only the second conductive layer 602, for example. Here, as shown in FIG. 14B, for example, the scanning signal line GL which is connected to the gate electrode GP1 in the display region DA has a portion thereof which passes the display region DA formed of the second conductive layer 602 and has a portion thereof which passes the peripheral region SA formed of the first conductive layer 601. Further, the first conductive layer 601 and the second conductive layer 602 which constitute one scanning signal line GL are, for example, electrically connected with each other in a state that an end portion of the second conductive layer 602 gets over an end portion of the first conductive layer 601 in a boundary between the display region DA and the peripheral region SA or in the vicinity of the boundary.

In the manufacturing method of the TFT substrate 1 having the constitution shown in the embodiment 3, in forming the gate electrodes GP1, GP2 and the scanning signal line GL, for example, first of all, the background insulation layer 101 such as a silicon nitride film is formed on the glass substrate 100 and, thereafter, the first conductive layer 601 is formed on the background insulation layer 101. Next, a resist is formed on the first conductive layer 601 and the first conductive layer 601 is etched to form the scanning signal lines GL, the gate electrodes GP2 of the MOS transistors of the first drive circuit DRV1 and the second drive circuit DRV2 and the like only outside (in the peripheral region SA) the display region DA.

Next, the second conductive layer 602 is formed on the glass substrate 100. Thereafter, a resist is formed on the second conductive layer 602, and the second conductive layer 602 is etched to form the scanning signal lines GL which are connected with the scanning signal line GL formed in the peripheral region SA, the gate electrodes GP1 of the TFT elements in the display region DA and the like only in the display region DA.

Here, for example, it is desirable that the first conductive layer 601 is formed of a material having heat conductivity lower than heat conductivity of a material (for example, aluminum) of the second conductive layer 602. In forming the first conductive layer 601, a film thickness of the first conductive layer 601 may be set smaller than a film thickness of the second conductive layer 602 so as to form the gate electrode GP2 or the like. Due to such a constitution, the TFT substrate 1 of this embodiment 3 can obtain the advantageous effects similar to the advantageous effects obtained by the TFT substrate 1 explained in conjunction with the embodiment 1 and the embodiment 2.

In the TFT substrate 1 having the constitution of the embodiment 3, for example, provided that the first conductive layer 601 is formed using a material having heat conductivity lower than heat conductivity of a material (for example, aluminum) of the second conductive layer 602, it is needless to say that, the respective conductive layers 601, 602 may have the substantially same thickness. However, to prevent the molten silicon from flowing down from an upper portion to a lower portion of the stepped portion and from causing peeling-off of the film at the stepped portion in steps for forming amorphous silicon SCa into polycrystalline silicon, it is desirable to form the first conductive layer 601 as thin as possible.

Although the present invention has been specifically explained in conjunction with the embodiments heretofore, it is needless to say that the present invention is not limited to the above-mentioned embodiments and various modifications can be made without departing from the gist of the present invention.

For example, provided that the TFT elements in the display region DA of the TFT substrate 1 and the MOS transistors of the first drive circuit DRV1 and the second drive circuit DRV2 have the bottom gate structure, the TFT elements and the MOS transistors are not limited to the structure shown in FIG. 4A to FIG. 4C and may adopt other structures.

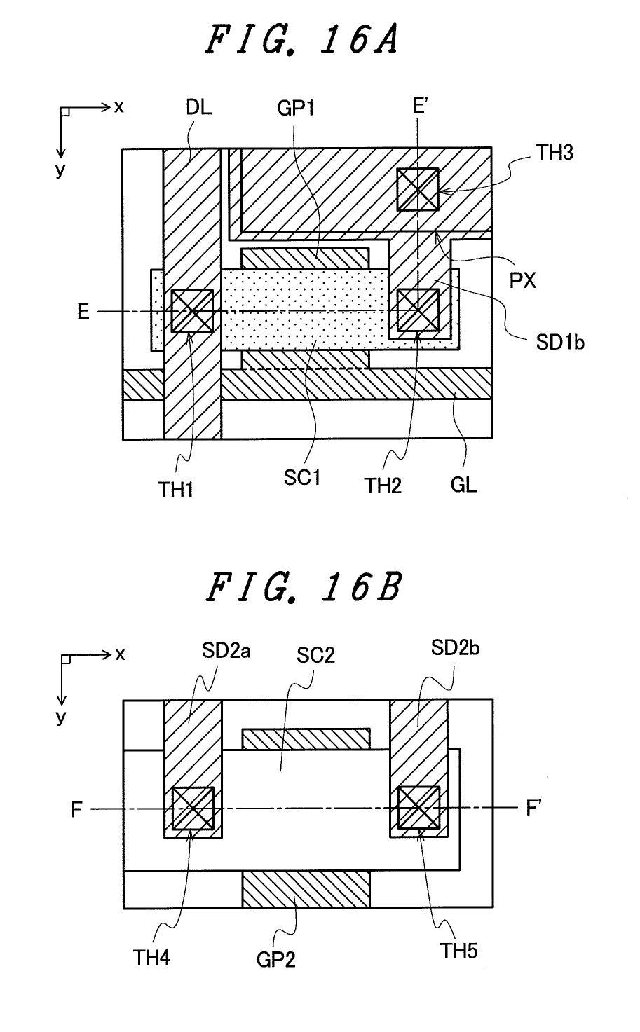

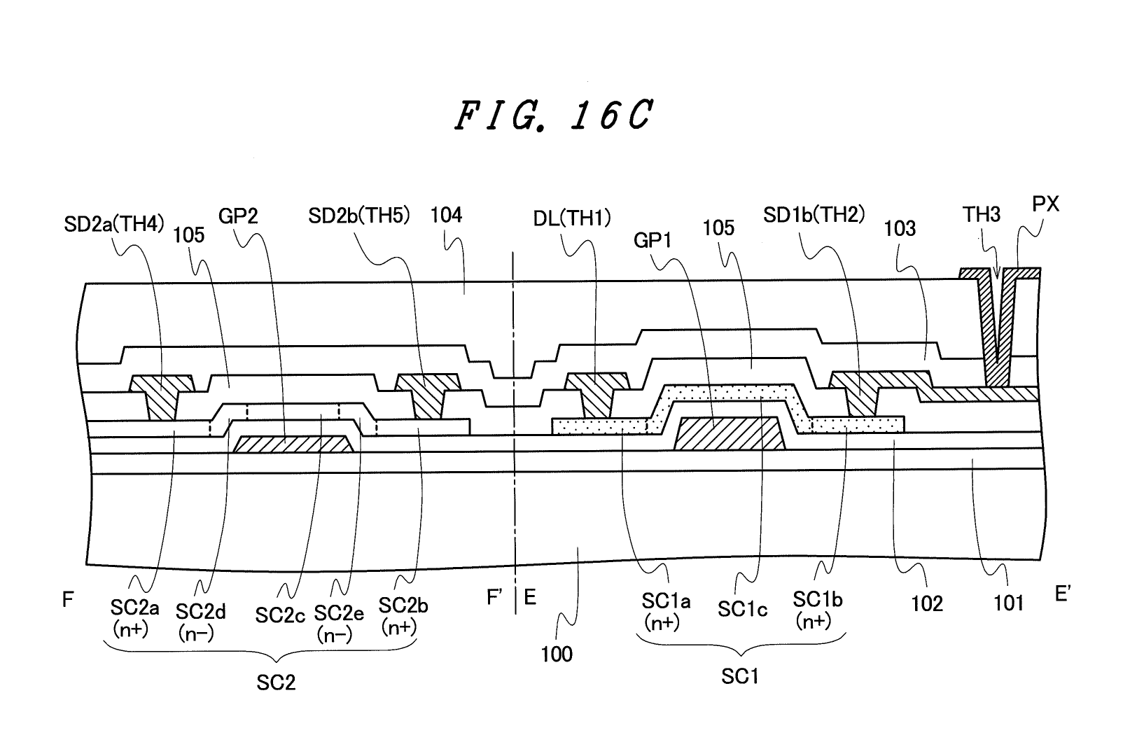

FIG. 15 and FIG. 16A to FIG. 16C are schematic views showing another example of the structure of the MOS transistor of the TFT substrate according to the present invention.

FIG. 15 is a schematic plan view for explaining a modification of the planar constitution of the TFT element shown in FIG. 4A.

FIG. 16A is a schematic plan view showing another example of the schematic constitution of the TFT element in the display region of the TFT substrate to which the present invention is applied. FIG. 16B is a schematic plan view showing another example of the schematic constitution of the MOS transistor of the peripheral circuit of the TFT substrate to which the present invention is applied. FIG. 16C is a schematic cross-sectional view showing one example of the cross-sectional constitution of the TFT substrate taken along a line E-E′ in FIG. 16A and one example of the cross-sectional constitution of the TFT substrate taken along a line F-F′ in FIG. 16B in a juxtaposed manner. Here, in FIG. 16C, (n+) indicates an n-type impurity region of high concentration, and (n−) indicates an n-type impurity region of low concentration.

In the embodiment 1 to the embodiment 3, the constitution in the periphery of the TFT element in the display region DA in a plan view is configured as shown in FIG. 4A, for example, wherein a rectangular projecting portion of the scanning signal line GL which is formed by partially increasing a width (a size in the y direction) of the scanning signal line GL is used as the gate electrode GP1. However, the planar constitution of the TFT element in the display region DA is not limited to such a constitution. For example, as shown in FIG. 15, while setting the width of the scanning signal line GL to a fixed value, the semiconductor layer SC1 may be formed on the scanning signal line GL. Further, also with respect to the video signal line DL, in place of using a rectangular projecting portion of the video signal line DL which is formed by partially increasing a width (a size in the x direction) of the video signal line DL as the drain electrode SD1a, for example, as shown in FIG. 15, it is needless to say that the semiconductor layer SC1 may be formed below the video signal line DL while setting the width of the video signal line DL to a fixed value.

Further, in allowing the TFT elements (MOS transistors) in the display region DA and the MOS transistors of the first drive circuit DRV1 and the second drive circuit DRV2 in the peripheral region SA to have the bottom gate constitution, the MOS transistor formed in each region DA, SA is not limited to have the constitution shown in FIG. 4A to FIG. 4C. For example, the MOS transistor may have the constitution shown in FIG. 16A to FIG. 16C. Here, the MOS transistor (TFT element) which is arranged in each pixel of the display region DA is configured, for example, as shown in FIG. 16A and FIG. 16C, wherein a gate electrode GP1 is formed on a background insulation layer 101 formed on a surface of the glass substrate 100. The gate electrode GP1 is, for example, integrally formed with the scanning signal line GL and is formed by making use of a rectangular projecting portion of the scanning signal line GL which is formed by partially increasing a width (size in the y direction) of the scanning signal line GL.

Further, as viewed from the glass substrate 100, on the gate electrode GP1, a semiconductor layer SC1 is formed by way of a first insulation layer (a gate insulation film) 102. The semiconductor layer SC1 is constituted of three regions consisting of a drain region SC1a, a source region SC1b and a channel region SC1c. Each region is formed of an amorphous semiconductor such as amorphous silicon. When the TFT element is an N-channel MOS transistor, the drain region SC1a and the source region SC1b of the semiconductor layer SC1 are formed of an n-type semiconductor region where phosphorus is implanted as impurities, and the channel region SC1c is formed of any one of an intrinsic (i-type) amorphous semiconductor, an n-type amorphous semiconductor of extremely low impurity concentration and a p-type amorphous semiconductor of extremely low impurity concentration.

Further, on the semiconductor layer SC1 as viewed from the glass substrate 100, the video signal line DL and the source electrode SD1b are formed by way of a fourth insulation layer 105, the video signal line DL is connected with the drain region SC1a of the semiconductor layer SC1 via a through hole TH1, and the source electrode SD1b is connected with the source region SC1b of the semiconductor layer SC1 via a through hole TH2.

Further, on the video signal line DL and the source electrode SD1b, the pixel electrode PX is formed by way of a second insulation layer 103 and a third insulation layer 104. The pixel electrode PX is connected with the source electrode SD1b via a through hole TH3.

Here, in the example shown in FIG. 16A, a width (a size in the x direction) of the video signal line DL is set to a fixed value, and the through hole TH1 is formed in a region where the video signal line DL and the semiconductor layer SC1 overlap each other in a plan view. However, the present invention is not limited to such an example. For example, it is needless to say that the width of the video signal line DL may be partially increased to form a rectangular projecting portion and such a projecting portion may be used as a drain electrode SD1a of the TFT element.

Here, the MOS transistor in the peripheral region, for example, is configured as shown in FIG. 16B and FIG. 16C, wherein the gate electrode GP2 is formed on the background insulation layer 101 formed on a surface of the glass substrate 100.

Further, as viewed from the glass substrate 100, on the gate electrode GP2, a semiconductor layer SC2 is formed by way of the first insulation layer 102. In adopting the N-channel MOS transistor as the MOS transistor in the peripheral region, for example, it is desirable that the N-channel MOS transistor has the LDD structure (lightly Doped Drain structure) in which the carrier moves more smoothly. Here, the semiconductor layer SC2 is constituted of five regions consisting of two drain regions SC2a, SC2d, two source regions SC2b, SC2e and a channel region SC2c. All of five regions are formed of a polycrystalline semiconductor such as polycrystalline silicon. Here, two drain regions SC2a, SC2d are formed of an N-type semiconductor region where P⁺ (phosphorus ion) is implanted as impurities, for example, and a region SC2d arranged close to the channel region SC2c exhibits impurity concentration lower than impurity concentration of a region SC2a arranged remote from the channel region SC2c. In the same manner, two source regions SC2b, SC2e are formed of an N-type semiconductor region where P⁺ (phosphorus ion) is implanted as impurities, for example, and a region SC2e arranged close to the channel region SC2c exhibits impurity concentration lower than impurity concentration of a region SC2b arranged remote from the channel region SC2c. Further, the channel region SC2c is formed of any one of an intrinsic (i-type) polycrystalline semiconductor, an n-type polycrystalline semiconductor of extremely low impurity concentration and a p-type polycrystalline semiconductor of extremely low impurity concentration. Particularly, when the semiconductor layer SC2 is formed of a polycrystalline semiconductor (polycrystalline silicon), a threshold value of the MOS transistor can be controlled by slightly adding impurities to the channel region SC2c.

Further, as viewed from the glass substrate 100, a drain electrode SD2a is formed on the drain region SC2a of the semiconductor layer SC2, and a source electrode SD2b is formed on the source region SC2b. The drain electrode SD2a is connected with the drain region SC2a via a through hole TH4, and the source electrode SD2b is connected with the source region SC2b via a through hole TH5.

Even when the TFT elements formed in the display region DA of the TFT substrate 1 and the MOS transistors of drive circuits DRV1, DRV2 formed in the peripheral region SA of the TFT substrate 1 are configured as shown in FIG. 16A to FIG. 16C, for example, by adopting the constitution explained in conjunction with the embodiment 1 to the embodiment 3 as the constitutions of the gate electrodes GP1, GP2 of the MOS transistors in the respective regions DA, SA, it is possible to obtain advantageous effects equal to the advantageous effects obtained by the TFT substrate 1 and the manufacturing method thereof enumerated in the respective embodiments.

Further, in forming the MOS transistor (TFT element) having the constitution shown in FIG. 16A and FIG. 16B, for example, after forming the amorphous silicon film SCa, and forming the amorphous silicon film SCa in the peripheral region SA into polycrystalline silicon, it is unnecessary to form the n-type amorphous silicon film explained in conjunction with the embodiment 1. In place of such formation of the n-type amorphous silicon film, for example, the amorphous silicon film SCa which is formed into polycrystalline silicon in a partial or whole area of the peripheral region SA is patterned in an island shape and, thereafter, the island-shaped amorphous silicon film SCa (semiconductor layer SC1) and the polycrystalline silicon film SCp (semiconductor layer SC2) are implanted with impurities thus forming the drain region SC1a and the source region SC1b of the semiconductor layer SC1 and the drain regions SC2a, SC2d and the source regions SC2b, SC2e of the semiconductor layer SC2. Here, steps for implanting impurities are equal to steps which are applied to a conventional manufacturing method of a TFT substrate land hence, the detailed explanation of the steps is omitted.

In this manner, provided that the TFT elements (MOS transistors) formed in the display region DA (first region) and the MOS transistors formed in the peripheral region SA (second region) adopt the bottom gate structure which includes the gate electrode between the substrate and the semiconductor layer and, at the same time, the semiconductor layer of the MOS transistor formed in one region is formed of the amorphous silicon film and the semiconductor layer of the MOS transistor formed in another region is formed of the polycrystalline silicon film, the present invention is applicable to the display device having any constitution.

Further, in the embodiment 1 to the embodiment 3, the case in which the semiconductor layers SC1 of the TFT elements in the display region DA are formed of amorphous silicon SCa and the semiconductor layers SC2 of the MOS transistors in the peripheral region SA are formed of polycrystalline silicon SCp which is amass of strip-like crystals is exemplified. However, the present invention is not limited to such a case, and it is needless to say that the present invention is also applicable to a case in which the semiconductor layers SC2 of the MOS transistors in the peripheral region SA are formed of, for example, polycrystalline silicon which is a mass of minute crystals 11p such as fine crystals or granular crystals shown on the upper side of the FIG. 8B.

Further, in the embodiment 1 to the embodiment 3, the case in which silicon is used as the semiconductor material for forming the semiconductor layers SC1, SC2 is exemplified. It is needless to say that, however, provided that a semiconductor material reforms a state thereof from an amorphous state to a polycrystalline state by heating, the semiconductor material is not limited to silicon and other semiconductor material may be used.

Further, it is needless to say that the present invention is not limited to the case in which the gate insulation film of the MOS transistor is formed of the oxide film and is also applicable to a case in which the gate insulation film is formed of an insulation film other than the oxide film. That is, the present invention is applicable to a TFT substrate which includes MIS transistors in which a semiconductor layer is formed of only amorphous semiconductor and an MIS transistor in which a semiconductor layer is formed of polycrystalline semiconductor.

Further, in forming the gate electrodes GP1, GP2 and the scanning signal line GL in accordance with the steps explained in conjunction with the embodiment 1 to the embodiment 3, it is desirable that the gate electrodes GP1 and the scanning signal lines GL in the display region DA are formed of a stacked line which is formed by stacking an MoW alloy, Al and an MoW alloy in order from below, and the gate electrodes GP2 and lines thereof in the peripheral region SA are formed of a single-layered line formed of an MoW alloy, for example.

Further, in the embodiment 1 to the embodiment 3, it is desirable that the gate electrodes GP1 and the scanning signal lines GL in the display region DA are collectively formed using the same process. That is, it is desirable that the scanning signal lines GL have the same stacked constitution as the gate electrodes GP1 in the display region DA and are integrally formed with the gate electrodes GP1.

The gate electrodes GP1 and the scanning signal lines GL may be formed using processes different from each other. In this case, however, by taking misalignment between the mask for forming the gate electrode GP1 and the mask for forming the scanning signal line GL into consideration, it is necessary to design masks for forming other constitutional elements in the inside of the pixel. Accordingly, it is necessary to ensure large margins for the respective masks and hence, there exists a possibility of lowering of a numerical aperture of the pixel, for example.

To the contrary, by forming the gate electrodes GP1 and the scanning signal lines GL collectively using the same process, margins for masks for forming other constitutional elements in the inside of the pixel can be reduced thus enhancing the numerical aperture of the pixel.

Further, in the embodiment 1 to the embodiment 3, for example, the explanation has been made with respect to the constitution and the manufacturing method of the gate electrodes GP1, GP2 when the present invention is applied to the TFT substrate 1 of the liquid crystal display panel having the constitution shown in FIG. 1A, FIG. 1B, FIG. 2 and FIG. 3. However, it is needless to say that the present invention is not limited to such a TFT substrate 1 of the liquid crystal display panel, and is also applicable to a substrate used in a self-luminous-type display panel or the like which uses organic EL (electro Luminescence), for example.

What is claimed is:

1. A display device having MIS transistors each of which is formed by stacking a conductive layer, an insulation layer and a semiconductor layer on a substrate, wherein
first MIS transistors formed in a first region of the substrate and second MIS transistors formed in a second region different from the first region respectively have gate electrodes thereof between the substrate and the semiconductor layers,
the first MIS transistor has the semiconductor layer thereof formed of only an amorphous semiconductor, and the second MIS transistor has the semiconductor layer thereof including a polycrystalline semiconductor, and
a gate electrode of the second MIS transistor has a thickness smaller than a thickness of a gate electrode of the first MIS transistor.

2. A display device according to claim 1, wherein the gate electrode of the first MIS transistor has wiring resistance lower than wiring resistance of the gate electrode of the second MIS transistor.

3. A display device according to claim 1, wherein the gate electrode of the second MIS transistor has heat conductivity lower than heat conductivity of the gate electrode of the first MIS transistor.

4. A display device according to claim 1, wherein the gate electrode of the first MIS transistor and the gate electrode of the second MIS transistor differ from each other in the stacking constitution of the conductive layer.

5. A display device according to claim 4, wherein the gate electrode of the first MIS transistor includes one or more conductive layers in addition to the stacking constitution of the conductive layer of the gate electrode of the second MIS transistor.

6. A display device according to claim 1, wherein the gate electrode of the first MIS transistor and the gate electrode of the second MIS transistor have the same stacking constitution of the conductive layer.

7. A display device according to claim 1, wherein the first region is a display region which displays videos or images, and the second region is a region which is arranged outside the display region and forms a drive circuit thereon.

8. A display device according to claim 7, wherein the display device includes scanning signal lines having the same stacking constitution as the gate electrodes of the first MIS transistors and being integrally formed with the gate electrodes of the first MIS transistors.

9. A manufacturing method of a display device which includes an insulation substrate, first MIS transistors which are formed on a first region on the insulation substrate and have semiconductor layers thereof formed of only an amorphous semiconductor, and second MIS transistors which are formed on the second region on the insulation substrate and have semiconductor layers thereof including a polycrystalline semiconductor, the manufacturing method comprising the steps of:
forming gate electrodes on the insulation substrate;
forming a gate insulation film which covers the gate electrodes;
forming an amorphous semiconductor film on the gate insulation film; and
melting and crystallizing only the amorphous semiconductor film in the second region out of the first region and the second region thus reforming the amorphous semiconductor film into polycrystalline semiconductor film, wherein
the step for forming the gate electrodes comprises a first step for forming a first conductive layer in the first region and the second region, and a second step for forming a second conductive layer only in the first region out of the first region and the second region; the step being a step in which the gate electrode of the first MIS transistor having the first conductive layer and the second conductive layer, and the gate electrode of the second MIS transistor having the first conductive layer and having a film thickness smaller than a film thickness of the gate electrode of the first MIS transistor are formed.

10. A manufacturing method of a display device according to claim 9, wherein the second step is performed after the first step, and
the second step is performed such that the second conductive layer is formed in the first region and the second region and, thereafter, the second conductive layer formed in the second region is removed.

11. A manufacturing method of a display device according to claim 9, wherein the second step is performed before the first step, and
the second step is performed such that the second conductive layer is formed in the first region and the second region and, thereafter, the second conductive layer formed in the second region is removed.

12. A manufacturing method of a display device according to claim 9, wherein the first conductive layer and the second conductive layer are formed of the same material.

13. A manufacturing method of a display device according to claim 9, wherein the first conductive layer and the second conductive layer are formed of materials which differ from each other, and
the first conductive layer is formed of a material having heat conductivity lower than heat conductivity of a material for forming the second conductive layer.

14. A manufacturing method of a display device according to claim 9, wherein the second conductive layer is formed of a material having wiring resistance lower than wiring resistance of a material for forming the first conductive layer.

15. A manufacturing method of a display device according to claim 9, wherein the manufacturing method includes;
a step for forming the first conductive layer and the second conductive layer sequentially on the insulation substrate;
a step for forming a first resist film which covers the second conductive layer, has a thickness larger than 0 in a region where the gate electrode of the second MIS transistor is formed, and has a thickness smaller than a thickness in a region where the gate electrode of the first MIS transistor is formed;
a step for removing the first conductive layer and the second conductive layer using the first resist film as a mask;
a step for forming a second resist film having a thickness of 0 in the region where the gate electrode of the second MIS transistor is formed and having a thickness larger than 0 in the region where the gate electrode of the first MIS transistor is formed by decreasing a thickness of the first resist film; and
a step for removing the second conductive layer in the region where the gate electrode of the second MIS transistor is formed using the second resist film as a mask.

16. A manufacturing method of a display device according to claim 9, wherein the first region is a display region which displays videos or images thereon, and the second region is a region which is arranged outside the display region and forms a drive circuit thereon.

17. A manufacturing method of a display device according to claim 16, wherein the display device includes scanning signal lines having the same stacking constitution as the gate electrodes of the first MIS transistors and being integrally formed with the gate electrodes of the first MIS transistors.
